(19) United States
(12) Patent Application Publication
(10) Pub. No.: US 2026/0215107 A1
(43) Pub. Date: Jul. 23, 2026

(54) DISPLAY PANEL AND METHOD FOR PREPARING SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yuanqi ZHANG, Beijing (CN); Weiyun HUANG, Beijing (CN); Yi ZHANG, Beijing (CN); Zhiwen CHU, Beijing (CN); Hongwei MA, Beijing (CN); Xiping LI, Beijing (CN); Kai YANG, Beijing (CN); Ying LIU, Beijing (CN); Lei FAN, Beijing (CN); Ke CHANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/992,582

(22) PCT Filed: May 16, 2024
(86) PCT No.: PCT/CN2024/093654

§ 371 Date: Jan. 9, 2025

(30) Foreign Application Priority Data
Jun. 30, 2023 (CN) 202310801942.9

(51) Int. Cl. H10K 59/131; H10K 59/12; H10K 59/122; H10K 59/80; H10K 102/00

(52) U.S. Cl. CPC H10K 59/131; H10K 59/1201; H10K 59/122; H10K 59/873; H10K 2102/351

(57) ABSTRACT

Disclosed is a display panel. In the display panel, a first trace layer of a power supply trace has a first target region exposed by a through-slot region of a first organic film layer, and an orthographic projection of a third material layer of the first trace layer disposed in the first target region is within an orthographic projection of a second material layer on the base substrate. An orthographic projection of a second material layer of the first trace layer on the base substrate is within an orthographic projection of the first material layer on the base substrate.

### CROSS-REFERENCE TO RELATED APPLICATIONS

The present disclosure is a U.S. national phase application based on PCT/CN2024/093654, filed on May 16, 2024, which claims priority to Chinese Patent Application No. 202310801942.9, filed on Jun. 30, 2023, and entitled “DISPLAY PANEL AND METHOD FOR PREPARING SAME, AND DISPLAY DEVICE”, both of which are incorporated by reference herein.

### TECHNICAL FIELD

The present disclosure relates to the field of display technologies, and in particular, relates to a display panel and a method for preparing the same, and display device.

### BACKGROUND

Organic light-emitting diode (OLED) display panels have become the mainstream development direction in the field of display technology due to their advantages of self-emission, high brightness, good image quality, and low energy consumption.

### SUMMARY

The present disclosure provides a display panel and a method for preparing the same, and display device. The technical solutions are as follows.

In one aspect, a display panel is provided. The display panel includes:
a base substrate, having a display region and a peripheral region surrounding the display region;
a plurality of pixel units, disposed in the display region;
a barrier structure, surrounding the display region;
at least one power supply trace, disposed on a side of the base substrate, wherein each of the at least one power supply trace is configured to receive a power supply signal and connected to the plurality of pixel units;
a first organic film layer, disposed on a side of the power supply trace away from the base substrate and provided with at least one through-slot region, wherein an orthographic projection of the through-slot region on the base substrate and an orthographic projection of the barrier structure on the base substrate are adjacent, and the through-slot region is configured to expose a first target region of the power supply trace;
wherein the power supply trace includes at least a first trace layer including a first material layer, a second material layer, and a third material layer that are stacked sequentially in a direction away from the base substrate, wherein an orthographic projection of a third material layer of the first trace layer in the first target region on the base substrate is within an orthographic projection of the second material layer on the base substrate, and an orthographic projection of a second material layer of the first trace layer in the first target region on the base substrate is within an orthographic projection of the first material layer on the base substrate.

In some embodiments, a first material layer of the first trace layer disposed in the first target region has a first boundary extending in a first direction, and the second material layer of the first trace layer disposed in the first target region has a second boundary extending in the first direction, and the third material layer of the first trace layer disposed in the first target region has a third boundary extending in the first direction;
wherein a distance, in a second direction, between the first boundary and the third boundary is greater than 3 micrometers, and the second boundary is disposed between the first boundary and the third boundary, the second direction being perpendicular to the first direction.

In some embodiments, the first organic film layer is provided with a groove region, a thickness of the first organic film layer in the groove region being less than a thickness of the first organic film layer in other regions except the groove region, and the groove region being configured to cover a second target region of the first trace layer;
wherein the second target region and the first target region are adjacent in a first direction.

In some embodiments, the groove region has a first groove boundary close to the first trace layer and extending in the first direction, and the third material layer of the first trace layer disposed in the first target region has a third boundary extending in the first direction;
wherein an orthographic projection of the first groove boundary on the base substrate is collinear with an orthographic projection of the third boundary on the base substrate.

In some embodiments, the groove region further has a second groove boundary away from the through-slot region and extending in a second direction and a third groove boundary adjacent to the through-slot region and extending in the second direction, the second direction being perpendicular to the first direction;
wherein a distance, in the first direction, between the second groove boundary and the third groove boundary is greater than 3 micrometers.

In some embodiments, the power supply trace includes a third trace layer, a second trace layer, and the first trace layer that are stacked sequentially in the direction away from the base substrate; and the display panel includes a third organic film layer disposed between the third trace layer and the second trace layer and a second organic film layer disposed between the second trace layer and the first trace layer, the first organic film layer being disposed on a side of the first trace layer away from the base substrate;
wherein the third trace layer and the second trace layer are connected through an first opening, the second trace layer and the first trace layer are connected through an second opening; wherein the first opening is in the third organic film layer, the second opening is in the second organic film layer, and the through-slot region is configured to expose the first target region of the first trace layer.

In some embodiments, the power supply trace includes a second trace layer and the first trace layer that are stacked sequentially in the direction away from the base substrate; and the display panel includes a second organic film layer disposed between the second trace layer and the first trace layer, the first organic film layer being disposed on a side of the first trace layer away from the base substrate;
wherein the second trace layer and the first trace layer are connected through an opening in the second organic film layer, and the through-slot region is configured to expose the first target region of the first trace layer.

In some embodiments, the at least one power supply trace includes a first signal power supply trace and a second signal power supply trace that are spaced apart in a second direction, and the through-slot region has a first sub-through-slot region for exposing the first signal power supply trace and a second sub-through-slot region for exposing the second signal power supply trace;
wherein a length of the first sub-through-slot region in a first direction is less than or equal to a length of the second sub-through-slot region in the first direction.

In some embodiments, a thickness of a portion of the second material layer disposed in the first target region is less than or equal to a thickness of a portion of the second material layer disposed in other regions.

In some embodiments, in the case that the thickness of the portion of the second material layer disposed in the first target region is less than the thickness of the portion of the second material layer disposed in the other regions, and a surface, away from the base substrate, of the portion of the second material layer disposed in the first target region is uneven.

In some embodiments, the barrier structure includes a first barrier dam, a second barrier dam, and a third barrier dam that are arranged sequentially in a direction away from the display region;
wherein the first organic film layer is provided with two through-slot regions, wherein one of the through-slot regions is disposed on a side of the third barrier dam away from the display region, and another of the through-slot regions is disposed between the second barrier dam and the third barrier dam.

In some embodiments, each barrier dam in the barrier structure includes at least one of organic film layers in the display panel, the organic film layers in the display panel including a third organic film layer, a second organic film layer, and the first organic film layer;
wherein one of the first organic film layer, the second organic film layer, and the third organic film layer is disposed in a region adjacent to any barrier dam in the barrier structure and not provided with the through-slot region.

In some embodiments, in a region of the power supply trace that is covered by an organic film layer in the display panel, side edges of the third material layer, the second material layer, and the first material layer are flat side edges, and the flat side edges are inclined relative to a carrying surface of the base substrate;
wherein an orthographic projection of the third material layer on the base substrate is within the orthographic projection of the second material layer on the base substrate, and the orthographic projection of the second material layer on the base substrate is within the orthographic projection of the first material layer on the base substrate.

In another aspect, a method for preparing a display panel is provided. The method includes:
providing a base substrate, wherein the base substrate has a display region and a peripheral region surrounding the display region;
forming a plurality of pixel units, a barrier structure, and at least one initial power supply trace on a side of the base substrate, wherein the plurality of pixel units are disposed in the display region, the barrier structure surrounds the display region, and each of the at least one initial power supply trace is configured to receive a power supply signal and connected to the plurality of pixel units; and the initial power supply trace includes at least a first initial trace layer including a first material layer, a second material layer, and a third material layer that are stacked sequentially in a direction away from the base substrate;
forming an initial organic film layer on a side of the initial power supply trace away from the base substrate, wherein the initial organic film layer is provided with at least one through-slot region, an orthographic projection of the through-slot region on the base substrate and an orthographic projection of the barrier structure on the base substrate being adjacent, and the through-slot region being configured to expose a first target region of the initial power supply trace; and
acquiring a first trace layer of at least one power supply trace and a first organic film layer by etching, using an etching process, a third material layer of the first initial trace layer of the at least one initial power supply trace disposed in the first target region and etching the initial organic film layer, wherein an orthographic projection of a third material layer of the first trace layer disposed in the first target region on the base substrate is within an orthographic projection of the second material layer on the base substrate, and an orthographic projection of a second material layer of the first trace layer disposed in the first target region on the base substrate is within an orthographic projection of the first material layer on the base substrate.

In some embodiments, forming the plurality of pixel units includes forming an anode layer, a pixel definition layer, a light-emitting layer, and a cathode layer sequentially on a side of the initial organic film layer away from the base substrate; and
etching, using the etching process, the third material layer of the first initial trace layer of the at least one initial power supply trace disposed in the first target region and etching the initial organic film layer includes:
etching, after forming the anode layer and before forming the pixel definition layer, the third material layer of the first initial trace layer of the at least one initial power supply trace disposed in the first target region and etching the initial organic film layer using the etching process.

In some embodiments, before forming the anode layer, a first boundary of a first material layer of the first initial trace layer disposed in the first target region, a second boundary of the second material layer of the first initial trace layer disposed in the first target region, and a third boundary of the third material layer of the first initial trace layer disposed in the first target region are collinear; and
after forming the anode layer, an orthographic projection of the second material layer of the first initial trace layer disposed in the first target region on the base substrate is within an orthographic projection of the third material layer on the base substrate, and the first boundary of the first material layer of the first initial trace layer disposed in the first target region and the third boundary of the third material layer are collinear;
wherein the first boundary, the second boundary, and the third boundary all extend in a first direction.

In some embodiments, forming the plurality of pixel units includes forming an anode layer, a pixel definition layer, a light-emitting layer, and a cathode layer sequentially on a side of the first organic film layer away from the base substrate; and
etching, using the etching process, the third material layer of the first initial trace layer of the at least one initial power supply trace disposed in the first target region and etching the initial organic film layer includes:
etching, after forming the pixel definition layer and before forming the light-emitting layer, the third material layer of the first initial trace layer of the at least one initial power supply trace disposed in the first target region and etching the initial organic film layer using the etching process.

In some embodiments, before forming the pixel definition layer, the orthographic projection of the second material layer of the first initial trace layer disposed in the first target region on the base substrate is within the orthographic projection of the third material layer on the base substrate, and the first boundary of the first material layer of the first initial trace layer disposed in the first target region and the third boundary of the third material layer are collinear;
after forming the pixel definition layer, a portion of a material of the pixel definition layer is disposed in an indented region, the indented region being a region where the first initial trace layer is provided with a first material layer and a third material layer and not provided with a second material layer; and
after etching, using the etching process, the third material layer of the first initial trace layer of the at least one initial power supply trace disposed in the first target region and etching the initial organic film layer, the portion of the material of the pixel definition layer in the indented region is removed.

In some embodiments, etching, using the etching process, the third material layer of the first initial trace layer of the at least one initial power supply trace disposed in the first target region, and etching the initial organic film layer includes:
coating a photoresist on a side of the first initial trace layer away from the base substrate;
exposing the photoresist using a mask;
developing the photoresist using a developer to remove a portion of the photoresist as exposed;
removing, using the etching process, a portion of the third material layer of the first initial trace layer disposed in the first target region and a portion of the initial organic film layer that are not protected by the photoresist; and
removing the remaining photoresist.

In some embodiments, the mask has a plurality of mask openings, wherein an orthographic projection of each of the mask openings on the base substrate partially overlaps the through-slot region and partially overlaps the first target region of the initial power supply trace; and
the mask opening has a first mask boundary extending in a first direction, wherein the first mask boundary is configured to form a third boundary of the third material layer that is etched, and an orthographic projection of the first mask boundary on the base substrate is within the orthographic projection of the first material layer on the base substrate, and a distance, in a second direction, between the first mask boundary and the first boundary is greater than 3 micrometers, the second direction being perpendicular to the first direction.

In some embodiments, the first mask boundary is further configured to form a first groove boundary of a groove region of the first organic film layer that is etched, the first groove boundary being close to the first trace layer and extending in the first direction;
a thickness of the first organic film layer in the groove region is less than a thickness of the first organic film layer in other regions except the groove region, and the groove region is configured to cover a second target region of the power supply trace, the second target region and the first target region being adjacent in the first direction.

In some embodiments, the mask opening further has a second mask boundary extending in the second direction, wherein the through-slot region is disposed on a side of the second mask boundary, and the second mask boundary is configured to form a second groove boundary of the groove region of the first organic film layer that is away from the through-slot region and extends in the second direction; and the groove region further has a third groove boundary adjacent to the through-slot region and extending in the second direction;
wherein a distance, in the first direction, between the second groove boundary and the third groove boundary is greater than 3 micrometers.

In some embodiments, forming the power supply trace includes: forming a first trace layer on the side of the base substrate; or
forming the power supply trace includes: forming a second trace layer, a second organic film layer, and the first trace layer sequentially on the side of the base substrate, the first trace layer and the second trace layer being connected through an opening in the second organic film layer; or
forming the power supply trace includes: forming a third trace layer, a third organic film layer, a second trace layer, a second organic film layer, and the first trace layer sequentially on the side of the base substrate, the first trace layer and the second trace layer being connected through an opening in the second organic film layer, and the second trace layer and the third trace layer being connected through an opening in the third organic film layer;
wherein the through-slot region is configured to expose a first target region of the first trace layer.

In yet another aspect, a display device is provided. The display device includes a power supply assembly and a display panel as described in the above aspects;
wherein the power supply assembly is configured to supply power to the display panel.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic structural diagram of a display panel according to some embodiments of the present disclosure;

FIG. 2 is a partial schematic diagram of the display panel shown in FIG. 1;

FIG. 3 is a schematic diagram of a base substrate according to some embodiments of the present disclosure;

FIG. 4 is a schematic stacked diagram of a power supply trace according to some embodiments of the present disclosure;

FIG. 5 is a schematic diagram of a power supply trace being side-etched according to some embodiments of the present disclosure;

FIG. 6 is a schematic diagram of a power supply trace according to some embodiments of the present disclosure;

FIG. 7 is a partial view of FIG. 2;

FIG. 8 is a cross-sectional view of FIG. 7 along the AA direction;

FIG. 9 is a cross-sectional view of FIG. 7 along the BB direction;

FIG. 10 is a cross-sectional view of FIG. 7 along the CC direction;

FIG. 11 is a cross-sectional view of FIG. 7 along the DD direction;

FIG. 12 is a cross-sectional view of FIG. 7 along the EE direction;

FIG. 13 is a flowchart of a method for preparing a display panel according to some embodiments of the present disclosure;

FIG. 14 is a flow chart of another method for preparing a display panel according to some embodiments of the present disclosure;

FIG. 15 is a schematic diagram of a process for etching a third material layer according to some embodiments of the present disclosure;

FIG. 16 is a flowchart of yet another method for preparing a display panel according to some embodiments of the present disclosure;

FIG. 17 is a schematic diagram of forming an active film according to some embodiments of the present disclosure;

FIG. 18 is a schematic diagram of patterning an active film according to some embodiments of the present disclosure;

FIG. 19 is a schematic diagram of forming a first insulating layer according to some embodiments of the present disclosure;

FIG. 20 is a schematic diagram of forming a first gate film according to some embodiments of the present disclosure;

FIG. 21 is a schematic diagram of patterning a first gate film according to some embodiments of the present disclosure;

FIG. 22 is a schematic diagram of forming a second insulating layer according to some embodiments of the present disclosure;

FIG. 23 is a schematic diagram of forming a second gate film according to some embodiments of the present disclosure;

FIG. 24 is a schematic diagram of patterning a second gate film according to some embodiments of the present disclosure;

FIG. 25 is a schematic diagram of forming an interlayer dielectric layer according to some embodiments of the present disclosure;

FIG. 26 is a schematic diagram of forming a first source-drain film according to some embodiments of the present disclosure;

FIG. 27 is a schematic diagram of coating a photoresist on a side of a first source-drain film away from a base substrate according to some embodiments of the present disclosure;

FIG. 28 is a schematic diagram of exposing and developing a photoresist according to some embodiments of the present disclosure;

FIG. 29 is a schematic diagram of etching a first source-drain film according to some embodiments of the present disclosure;

FIG. 30 is a schematic diagram of removing a photoresist according to some embodiments of the present disclosure;

FIG. 31 is a schematic diagram of forming a first planarization film according to some embodiments of the present disclosure;

FIG. 32 is a schematic diagram of patterning a first planarization film according to some embodiments of the present disclosure;

FIG. 33 is a schematic diagram of forming an anode film according to some embodiments of the present disclosure;

FIG. 34 is a schematic diagram of patterning an anode film according to some embodiments of the present disclosure;

FIG. 35 is a schematic diagram of forming a pixel definition film according to some embodiments of the present disclosure;

FIG. 36 is a schematic diagram of patterning a pixel definition film according to some embodiments of the present disclosure;

FIG. 37 is a schematic diagram of coating a photoresist after an anode layer is prepared according to some embodiments of the present disclosure;

FIG. 38 is a schematic diagram of exposing and developing a photoresist according to some embodiments of the present disclosure;

FIG. 39 is a schematic diagram of etching a third material layer according to some embodiments of the present disclosure;

FIG. 40 is a schematic diagram of removing a photoresist according to some embodiments of the present disclosure;

FIG. 41 is a schematic diagram of coating a photoresist after a pixel definition layer is prepared according to some embodiments of the present disclosure;

FIG. 42 is a schematic diagram of exposing and developing a photoresist according to some embodiments of the present disclosure;

FIG. 43 is a schematic diagram of etching a third material layer according to some embodiments of the present disclosure;

FIG. 44 is a schematic diagram of removing a photoresist according to some embodiments of the present disclosure;

FIG. 45 is a flowchart of a further method for preparing a display panel according to some embodiments of the present disclosure;

FIG. 46 is a flowchart of a further method for preparing a display panel according to some embodiments of the present disclosure;

FIG. 47 is a flowchart of a further method for preparing a display panel according to some embodiments of the present disclosure;

FIG. 48 is a flowchart of a further method for preparing a display panel according to some embodiments of the present disclosure;

FIG. 49 is an electron microscope schematic diagram of an I-shaped structure of a region of a first trace layer not covered by an organic film layer according to some embodiments of the present disclosure;

FIG. 50 is an electron microscope schematic diagram of a region where a first trace layer is covered by an organic film layer according to some embodiments of the present disclosure;

FIG. 51 is an electron microscope schematic of the presence of remaining pixel definition material in an I-shaped structure according to some embodiments of the present disclosure;

FIG. 52 is an electron microscope schematic of etching a third material layer according to some embodiments of the present disclosure;

FIG. 53 is another electron microscope schematic of etching a third material layer according to some embodiments of the present disclosure;

FIG. 54 is a partially enlarged schematic of the electron microscope schematic shown in FIG. 53; and

FIG. 55 is a schematic structural diagram of a display device according to some embodiments of the present disclosure.

### DETAILED DESCRIPTION

To make the objective, technical solutions, and advantages of the present disclosure clearer, embodiments of the present disclosure will be further described in detail referring to the accompanying drawings.

In the related art, a display panel has a display region and a peripheral region surrounding the display region. The display panel includes a barrier structure located in the peripheral region and surrounding the display region to block the overflow of organic material from the display region. In order to avoid water and oxygen intrusion from the surrounding region to the display region along the organic material, an organic film layer located in the region next to the barrier structure needs to be removed. Moreover, the display panel includes a power supply trace, and the power supply trace needs to pass through the barrier structure from the peripheral region and be connected to the relevant structure of the pixel units in the display region, thereby providing a power supply signal to the relevant structure of the pixel units.

However, as the organic film layer located in the region next to the barrier structure needs to be removed, the power supply trace is exposed at the location where the organic film layer is removed. During the preparation of the film layer after the power supply trace, the exposed portion of the power supply trace may be side-etched, thereby affecting the yield of the display panel, and the display effect of the display panel is poor.

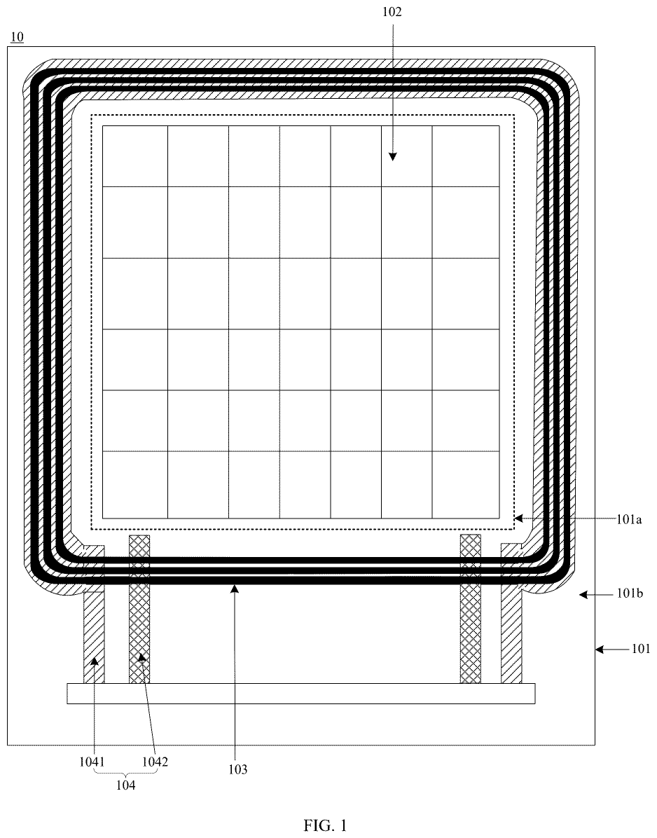

FIG. 1 is a schematic structural diagram of a display panel 10 according to some embodiments of the present disclosure. FIG. 2 is a partial schematic diagram of the display panel 10 shown in FIG. 1. Referring to FIGS. 1 and 2, the display panel 10 includes a base substrate 101, a plurality of pixel units 102, a barrier structure 103, at least one power supply trace 104, and a first organic film layer 105.

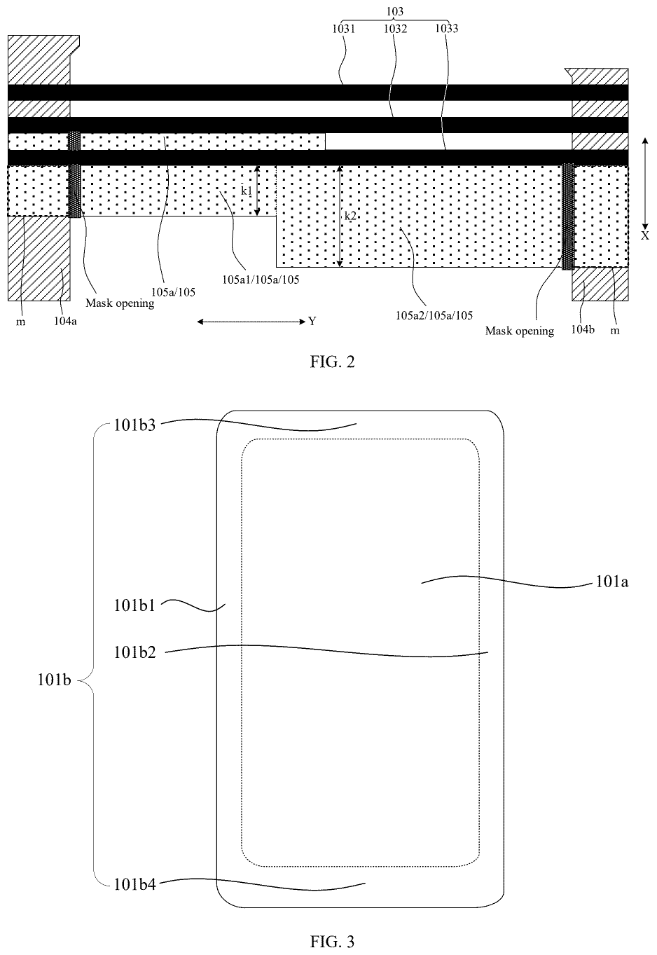

FIG. 3 is a schematic diagram of a base substrate according to some embodiments of the present disclosure. Referring to FIG. 3, the base substrate 101 has a display region 101a and a peripheral region 101b surrounding the display region 101a. Combined with FIGS. 1 to 3, the plurality of pixel units 102 are disposed in the display region 101a, and the barrier structure 103 is disposed in the peripheral region 101b and surrounds the display region 101a to avoid the overflow of organic material in the display region 101a.

The at least one power supply trace 104 are disposed on a side of the base substrate 101, and each of the power supply traces 104 is configured to receive a power supply signal and connected to the pixel units 102. Therefore, each of the power supply traces 104 may be used for transmitting the power supply signal to the pixel units 102, thereby driving the pixel units 102 to emit light.

The first organic film layer 105 is disposed on a side of the power supply traces 104 away from the base substrate 101, and the first organic film layer 105 has at least one through-slot region 105a. An orthographic projection of the through-slot region 105a on the base substrate 101and an orthographic projection of the barrier structure 103 on the base substrate 101 are adjacent, and the through-slot region 105a is configured to expose a first target region m of the power supply traces 104.

As the material of the first organic film layer 105 is an organic material, the external water and oxygen may intrude the display region 101a along the first organic film layer 105, causing the pixel units 102 of the display region 101a to fail. Thus, to avoid the failure of the pixel units 102, the first organic film layer 105 disposed at an adjacent position of the barrier structure 103 may be removed, i.e., the through-slot region 105a designed in the first organic film layer 105 and the barrier structure 103 are arranged adjacent to each other. Further, as the first organic film layer 105 at the adjacent position of the barrier structure 103 is removed, the first target region m in the power supply trace 104 disposed in the removed first organic film layer 105 is exposed, i.e., the first target region m of the power supply trace 104 is exposed from the through-slot region 105a of the first organic film layer 105.

The power supply trace 104 includes at least a first trace layer. Referring to FIG. 4, the first trace layer includes a first material layer a1, a second material layer a2, and a third material layer a3 that are stacked sequentially in a direction away from the base substrate 101. Typically, the material of the first material layer a1 and the material of the third material layer a3 are the same, e.g., the material of the first material layer a1 and the third material layer a3 is titanium (Ti), and the material of the second material layer a2 is different from the material of the first material layer a1 and the third material layer a3, e.g., the material of the second material layer a2 is aluminum (Al). Moreover, the display panel 10 also includes other film layers disposed on the side of the power supply trace 104 away from the base substrate 101. During the subsequent preparation of these other film layers, as the portion of the first trace layer of the power supply trace 104 disposed in the first target region m is exposed, the portion of the first trace layer of the power supply trace 104 disposed in the first target region m is susceptible to the process influence. As the material of the second material layer a2 is easier to be etched than the material of the first material layer a1 (the third material layer a3), referring to FIG. 5, the first trace layer is susceptible to being side-etched, and the first trace layer is in an I-shaped (undercut) structure.

Further, the display panel 10 also includes an encapsulation film layer (not shown in the drawings) for encapsulating the display region 101a, and the inorganic material layer included in the encapsulation film layer is prone to cracks at a location where the power supply trace 104 is in an I-shaped structure. The presence of the crack provides an intrusion channel for the intrusion of water and oxygen, which diffuses along the intrusion channel to the display region 101a, leading to the failure of the pixel units 102 of the display region 101a, resulting in the problem of black-spot defects in the display region 101a.

As can be seen from the above analysis, the main reason for the failure of the pixel units 102 in the display region 101a is that the second material layer a2 in the portion of the first trace layer of the power supply trace 104 disposed in the first target region m (the first target region m is not protected by the first organic film layer 105) has been etched, resulting in the first trace layer being in an I-shaped structure.

In the related art, in order to solve the problem of water and oxygen intrusion caused by the I-shaped structure of the first trace layer, which in turn leads to the failure of the pixel units, an inorganic film layer (for example, a passivation layer (PVX)) is usually formed on the side of the first trace layer of the power supply trace away from the base substrate 101, so as to make the inorganic film layer cover the region where the first trace layer is exposed by the first organic film layer, avoiding the formation of the subsequent film layer that causes the first trace layer to form an I-shaped structure.

However, the solution for forming the inorganic film layer leads to an increase in the process, such as the addition of processes such as inorganic film deposition, exposure, and development, which in turn affects the production capacity of the display panel. Moreover, in the case that the display panel includes a plurality of source-drain layer (e.g., including a first source-drain layer SD1, a second source-drain layer SD2, and a third source-drain layer SD3), the inorganic film layer can only be designed between SD1 and SD2, i.e., the power supply trace can only be routed using SD1 (the power supply trace is a single-layer trace), which is not conducive to lowering the power consumption of the display panel, and the flexibility of routing the power supply trace is poor.

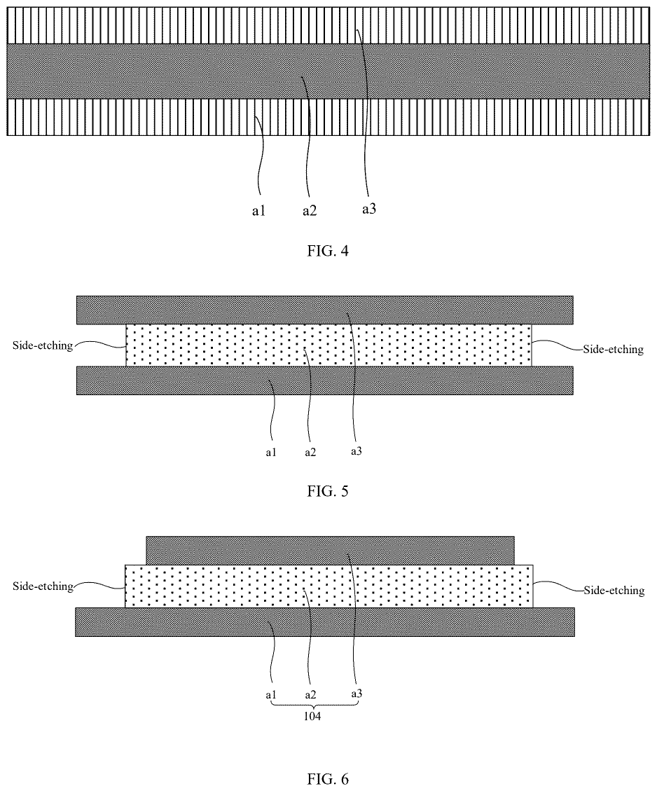

Thus, in the embodiments of the present disclosure, referring to FIG. 6, in order to solve the problem of the first trace layer of the power supply trace 104 being in an I-shaped structure, an orthographic projection of the third material layer a3 of the first trace layer of the power supply trace 104 disposed in the first target region m on the base substrate 101 is within an orthographic projection of the second material layer a2 on the base substrate 101. An orthographic projection of the second material layer a2 of the first trace layer of the power supply trace 104 disposed in the first target region m on the base substrate 101 is within an orthographic projection of the first material layer a1 on the base substrate 101.

It should be noted that after the other film layers included in the display panel 10 that are disposed on the side of the power supply trace 104 away from the base substrate 101 are prepared, as the second material layer a2 of the first trace layer of the power supply trace 104 in the first target region m is etched, it is possible to cause the orthographic projection of the second material layer a2 of the first trace layer of the power supply trace 104 in the first target region m on the base substrate 101 to be disposed within the orthographic projection of the first material layer a1 on the base substrate 101. Further, referring to FIG. 6, after the subsequent film layer preparation is completed, the third material layer a3 of the first trace layer of the power supply trace 104 in the first target region m may be etched using an etching process, such that the orthographic projection of the third material layer a3 of the power supply trace 104 in the first target region m on the base substrate 101 is within the orthographic projection of the second material layer a2 on the base substrate 101, thereby avoiding the portion of the first trace layer of the power supply trace 104 in the first target region m to be in an I-shaped structure.

Further, the inorganic material layer in the encapsulation film layer included in the display panel 10 can climb layer by layer in the first target region m, such that cracks in the inorganic material layer can be avoided, which in turn avoids water and oxygen intrusion. As a result, the light-emitting effect of the pixel units 102 in the display region 101a can be ensured, and the black-spot defects in the display region 101a can be avoided.

In summary, the embodiments of the present disclosure provide a display panel. In the display panel, a first trace layer of a power supply trace has a first target region exposed by a through-slot region of a first organic film layer, and an orthographic projection of a third material layer of the first trace layer in the first target region is within an orthographic projection of the second material layer on the base substrate. An orthographic projection of the second material layer of the first trace layer in the first target region on the base substrate is within an orthographic projection of the first material layer on the base substrate. As a result, the subsequent formation of an encapsulation film layer of the display panel can be prevented from generating cracks in the first target region, and thus water and oxygen can be prevented from intruding into the display region along the intrusion channel generated by the cracks. The solution of the embodiments of the present application can ensure the light-emitting effect of the pixel units in the display region, avoid the occurrence of black-spot defects in the display region, have a higher yield of the display panel, and have a better display effect of the display panel.

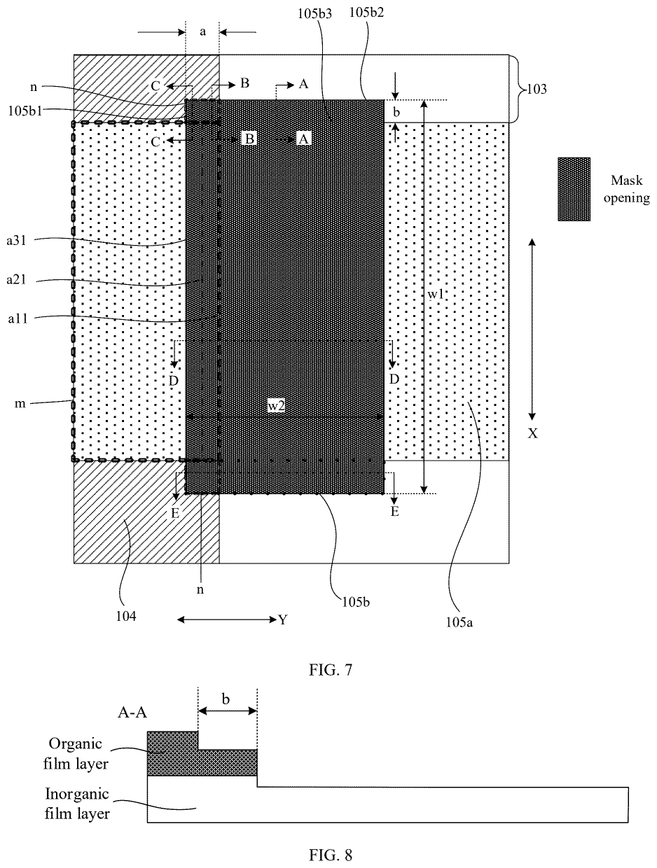

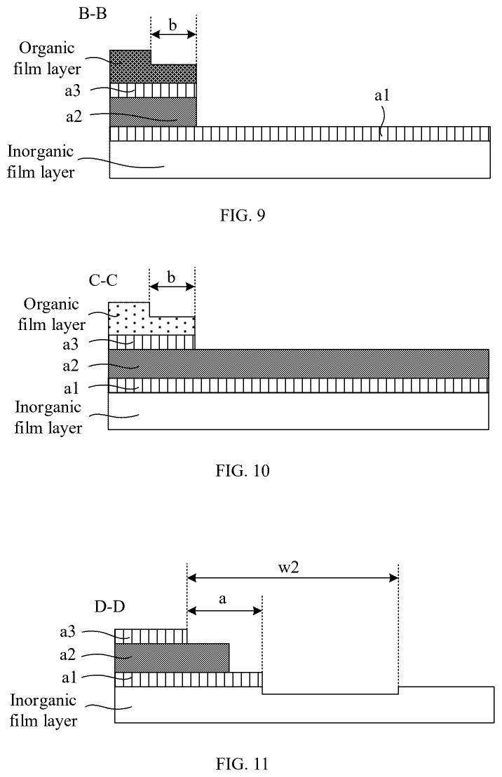

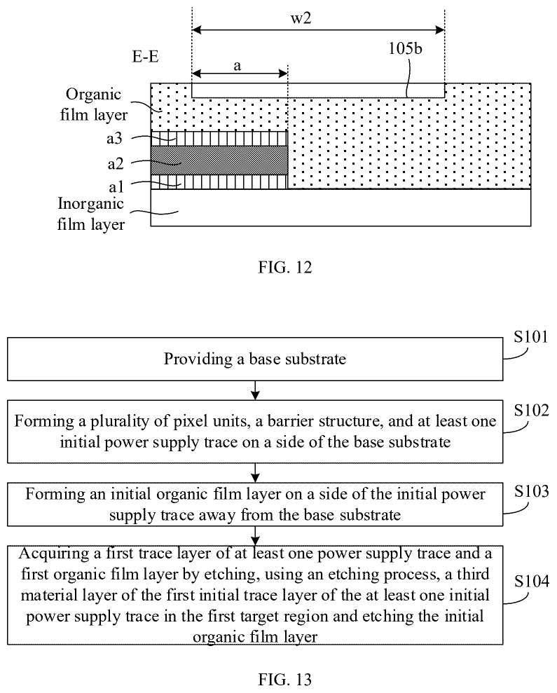

FIG. 7 is a partial view of FIG. 2. FIG. 8 is a cross-sectional view of FIG. 7 along the AA direction. FIG. 9 is a cross-sectional view of FIG. 7 along the BB direction. FIG. 10 is a cross-sectional view of FIG. 7 along the CC direction. FIG. 11 is a cross-sectional view of FIG. 7 along the DD direction, and FIG. 12 is a cross-sectional view of FIG. 7 along the EE direction. Combined with FIGS. 7 to 11, the first material layer a1 of the first trace layer of the power supply trace 104 disposed in the first target region m has a first boundary a11 extending in the first direction X. The first boundary a11 may be the midline of the side surface of the first material layer a1 in its thickness. The second material layer a2 of the first trace layer of the power supply trace 104 disposed in the first target region m has a second boundary a21 extending in the first direction X. The second boundary a21 may be the midline of the side surface of the second material layer a2 in its thickness. The third material layer a3 of the first trace layer of the power supply trace 104 disposed in the first target region m has a third boundary a31 extending in the first direction X. The third boundary a31 may be a midline of the side surface of the third material layer a3 in its thickness. The inorganic film layer in FIGS. 8 to 12 refers to a film layer in which all materials disposed on the side of the power supply trace 104 close to the base substrate are inorganic materials. The organic film layer in FIGS. 8 to 12 refers to a film layer in which material is an organic material, for example, the organic film layer includes a first organic film layer 105 disposed on the side, away from the base substrate 101, of the first trace layer of the power supply trace 104.

Typically, the size of the second material layer a2 that is side-etched during subsequent film layer preparation is typically less than 3 micrometers (μm). Therefore, in order to ensure that the orthographic projection of the third material layer a3 on the base substrate 101 is within the orthographic projection of the second material layer a2 on the base substrate 101, the distance between the first boundary a11 and the third boundary a31 in the second direction Y can be greater than 3 μm. The second boundary a21 is disposed between the first boundary a11 and the third boundary a31, such that the first material layer a1, the second material layer a2, and the third material layer a3 are in a step structure that increases layer by layer. The second direction Y is perpendicular to the first direction X. For example, the first direction X is a pixel column direction of the display panel 10, and the second direction Y is a pixel row direction of the display panel 10.

The second boundary a21 being disposed between the first boundary a11 and the third boundary a31 may mean that an orthographic projection of the second boundary a21 on the base substrate 101 is disposed between an orthographic projection of the first boundary a11 on the base substrate 101 and an orthographic projection of the third boundary a31 on the base substrate 101.

Assuming that the organic film layer shown in FIG. 12 is the first organic film layer 105, referring to FIG. 12, the first organic film layer 105 is provided with a groove region 105b, and the thickness h1 of the first organic film layer 105 disposed in the groove region 105b is less than the thickness h2 of the first organic film layer 105 in other regions except the groove region 105b. The groove region 105b is configured to cover a second target region n of the power supply trace 104. The second target region n and the first target region m are adjacent to each other in the first direction X.

In some embodiments, the same etching process may be used to etch the third material layer a3 of the first trace layer of the power supply trace 104 disposed in the first target region m, and to form the groove region 105b of the first organic film layer 105. For example, when performing the etching process, the same mask opening in the mask may be used to form the etched third material layer a3 and the groove region 105b. The length w1 of the etched region in the first direction X may be slightly larger than the length of the first target region m in the first direction X. The length w2 in the second direction Y may be determined based on the product, it is only necessary to ensure that the third boundary a31 of the first trace layer is away from the first boundary a11 relative to the second boundary a21.

Referring to FIG. 7, the groove region 105b has a first groove boundary 105b1 close to the first trace layer of the power supply trace 104 and extending in the first direction X. As the groove region 105b and the third material layer a3 are formed by the same etching process, assuming that the mask opening in the mask is a rectangular opening, an orthographic projection of the first groove boundary 105b1 on the base substrate 101 is collinear with an orthographic projection of the third boundary a31 on the base substrate 101.

As the second target region n and the first target region m of the first trace layer of the power supply trace 104 are adjacent to each other in the first direction X, the groove region 105b in the first organic film layer 105 covering the second target region n and the through-slot region 105a exposing the first target region m are adjacent to each other in the first direction X. Referring to FIG. 7, the groove region 105b also has a second groove boundary 105b2 away from the through-slot region 105a and extending in the second direction Y, and a third groove boundary 105b3 adjacent to the through-slot region 105a and extending in the second direction Y. The distance b between the second groove boundary 105b2 and the third groove boundary 105b3 in the first direction X is greater than 3 μm. Thus, etching the third material layer a3 of the power supply trace 104 disposed in the first target region m can be ensured, avoiding an I-shaped structure of the power supply trace 104 due to a small etching range.

In the embodiments of the present disclosure, when etching the third material layer a3 of the first trace layer of the power supply trace 104 disposed in the first target region m using the etching process, a portion of the second material layer a2 of the first trace layer disposed in the first target region m may also be etched away, and the second material layer a2 of the first trace layer disposed in the first target region m may not be etched away.

In the case that the portion of the second material layer a2 of the first trace layer disposed in the first target region m is etched away, the thickness of the portion of the second material layer a2 disposed in the first target region m is less than the thickness of a portion of the second material layer a2 disposed in other regions. In this case, the surface, away from the base substrate 101, of the portion of the second material layer a2 disposed in the first target region m is uneven. Follow-up with the improvement of the process, the surface, away from the base substrate 101, of the portion of the second material layer a2 disposed in the first target region (m) may be a flat surface.

In the case that the second material layer a2 of the first trace layer disposed in the first target region m is not etched away, the thickness of the portion of the second material layer a2 disposed in the first target region m may be equal to the thickness of the portion of the second material layer a2 disposed in the other regions.

As a first optional implementation, the display panel 10 includes an active layer (poly), a first insulating layer, a first gate layer (gate1), a second insulating layer, a second gate layer (gate2), a third insulating layer, an oxide layer (IGZO), a fourth insulating layer, a third gate layer (gate3), an inter-level dielectric (ILD), a first source-drain layer (SD1), a first planarization layer (PLN), a second source-drain layer (SD2), a second planarization layer (PLN), a third source-drain layer (SD3), and a third planarization layer (PLN3). That is, the display panel 10 has three source-drain layers. In this implementation, the organic film layer in FIGS. 8 to 12 includes a first planarization layer, a second planarization layer, and a third planarization layer; and the inorganic film layer in FIGS. 8 to 12 includes a first insulating layer, a second insulating layer, a third insulating layer, a fourth insulating layer, and an interlayer dielectric layer.

In this case, the power supply trace 104 may be routed using one, two, or three layers of the first source-drain layer (SD1), the second source-drain layer (SD2), and the third source-drain layer (SD3). That is, the power supply trace 104 may include one-layer trace, two-layer trace, or three-layer trace. In the case that the power supply trace 104 is a multi-layer trace scheme, it is necessary to ensure that the trace disposed in the upper layer covers the trace disposed in the lower layer, so as to avoid the trace in the lower layer being exposed, which affects the trace in the lower layer during the preparation of the subsequent film layer.

In some embodiments, the power supply trace 104 includes a third trace layer, a second trace layer, and a first trace layer that are stacked sequentially in a direction away from the base substrate 101. The third trace layer is disposed in the first source-drain layer (SD1) of the display panel 10, the second trace layer is disposed in the second source-drain layer (SD2), and the first trace layer is disposed in the third source-drain layer (SD3). The first planarization layer (the third organic film layer) between the first source-drain layer and the second source-drain layer has an opening, and the third trace layer and the second trace layer are connected through the opening in the first planarization layer. The second planarization layer (the second organic film layer) between the second source-drain layer and the third source-drain layer has an opening, and the second trace layer and the first trace layer are connected through the opening in the second planarization layer.

In some embodiments, in the position where the first organic film layer 105 is provided with the through-slot region 105a, the second organic film layer and the third organic film layer are also provided with through-slot regions 105a. That is, the region next to the barrier structure 103 where the first organic film layer 105 is removed, the second organic film layer and the third organic film layer are likewise removed. That is, the through-slot region 105a is the region where all of the film layers composed of organic material included in the display panel 10 are removed. As the first trace layer covers the second trace layer and the third trace layer, the design of the through-slot region 105a can expose the first target region m of the first trace layer without exposing the second trace layer and the third trace layer.

As a result, only the first trace layer disposed in the uppermost layer may be in an I-shaped structure during the preparation of the subsequent film layer, the third trace layer disposed in the first target region m in the first trace layer can be etched by the etching process to avoid the first trace layer being in an I-shaped. In this implementation, the power supply trace 104 shown in FIGS. 7 to 12 may be the first trace layer included in the power supply trace 104, and the second trace layer and the third trace layer are not shown in FIGS. 7 to 12.

In the embodiments of the present disclosure, in the case that the display panel 10 has three source-drain layers, the display panel 10 may be a low-temperature polycrystalline oxide (LTPO) display panel that includes oxide thin film transistors.

As a second optional implementation, the display panel 10 includes an active layer (poly), a first insulating layer, a first gate layer (gate1), a second insulating layer, a second gate layer (gate2), an interlayer dielectric layer (ILD), a first source-drain layer (SD1), a first planarization layer (PLN1), a second source-drain layer (SD2), and a second planarization layer (PLN2). That is, the display panel 10 has two source-drain layers.

In this case, the power supply trace 104 may be routed in one-layer or two-layer of the first source-drain layer and the second source-drain layer. That is, the power supply trace 104 may include a one-layer trace or a two-layer trace. In the case that the power supply trace 104 is a two-layer trace scheme, it is necessary to ensure that the trace disposed in the upper layer covers the trace disposed in the lower layer, so as to avoid the trace in the lower layer being exposed, which affects the trace in the lower layer during the preparation of the subsequent film layer.

In some embodiments, the power supply trace 104 includes a second trace layer and a first trace layer that are stacked sequentially in a direction away from the base substrate 101. The second trace layer is disposed in the first source-drain layer (SD1) of the display panel 10, and the first trace layer is disposed in the second source-drain layer (SD2). The first planarization layer (the second organic film layer) between the first source-drain layer and the second source-drain layer has an opening, and the second trace layer and the first trace layer are connected through the opening in the first planarization layer.

In some embodiments, in the position where the first organic film layer 105 is provided with the through-slot region 105a, the second organic film layer is also provided with a through-slot region 105a. That is, the region next to the barrier structure 103 where the first organic film layer 105 is removed, the second organic film layer is likewise removed. That is, the through-slot region 105a is the region where all of the film layers composed of organic material included in the display panel 10 are removed. As the first trace layer covers the second trace layer, the design of the through-slot region 105a can expose the first target region m of the first trace layer without exposing the second trace layer.

As a result, only the first trace layer disposed in the upper layer may be in an I-shaped structure during the preparation of the subsequent film layer, the third trace layer disposed in the first target region m in the first trace layer can be etched by the etching process to avoid the first trace layer being in an I-shaped. In this implementation, the power supply trace 104 shown in FIGS. 7 to 12 may be the first trace layer included in the power supply trace 104, and the second trace layer is not shown in FIGS. 7 to 12.

In the embodiments of the present disclosure, in the case that the display panel 10 has two source-drain layers, the display panel 10 may be a low-temperature poly-silicon (LTPS) display panel that includes LTPS thin film transistors.

As a third optional implementation, the display panel 10 includes an active layer (poly), a first insulating layer, a first gate layer (gate1), a second insulating layer, a second gate layer (gate2), an interlayer dielectric layer (ILD), a first source-drain layer (SD1), and a first planarization layer (PLN1). That is, the display panel 10 has one source-drain layer.

In this case, the power supply trace 104 may be routed using the first source-drain layer. That is, the power supply trace 104 may include a one-layer trace. In some embodiments, the power supply trace 104 includes a first trace layer, and the first planarization layer on the first trace layer may be the first organic film layer 105 as described in the above embodiments. In this implementation, the power supply trace 104 shown in FIGS. 7 to 12 may be the first layer trace included in the power supply trace 104.

In the embodiments of the present disclosure, in the case that the display panel 10 has one source-drain layer, the display panel 10 may be a low-temperature polycrystalline silicon (LTPS) display panel that includes LTPS thin film transistors.

Referring to FIG. 2, the at least one power supply trace 104 includes a first signal power supply trace 104a and a second signal power supply trace 104b that are spaced apart in the second direction Y. The first signal power supply trace 104a may provide a first signal to the pixel units 102, and the first signal power supply trace 104a may be a negative power supply trace (referred to as a VSS trace). The second signal power supply trace 104b may provide a second signal to the pixel units 102, and the second signal power supply trace 104b may be a positive power supply trace (referred to as a VDD trace).

Typically, other signal traces may be designed in the region where the VSS trace is provided, and the other signal traces may also be double-layer traces, with an insulating layer being required to insulate between the double-layer trace. Thus, referring to FIG. 2, the through-slot region 105a has a first sub-through-slot region 105a1 for exposing the first signal power supply trace 104a and a second sub-through-slot region 105a2 for exposing the second signal power supply trace 104b. The length k1 of the first sub-through-slot region 105a1 in the first direction X is less than or equal to the length k2 of the second sub-through-slot region 105a2 in the first direction X. Thereby, the first sub-through-slot region 105a1 where the VSS trace is arranged can be designed to be small, such that the region has an organic film layer to insulate the double-layer trace of other signal traces.

In the embodiments of the present disclosure, the orthographic projection of the power supply trace 104 on the base substrate 101 partially overlaps an orthographic projection of the barrier structure 103 on the base substrate 101. Therefore, a portion of the power supply trace 104 can be disposed on a side of the barrier structure 103 close to the display region 101a to be connected to the pixel units 102, and another portion of the power supply trace 104 can be disposed on a side of the barrier structure 103 away from the display region 101a to receive a power supply signal.

In some embodiments, the orthographic projection of the barrier structure 103 on the base substrate 101 may be an annular structure. The portion of the power supply trace 104 disposed on the side of the barrier structure 103 close to the display region 101a is within the region enclosed by the barrier structure 103. Another portion of the power supply trace 104 disposed on the side of the barrier structure 103 away from the display region 101a is disposed outside the region enclosed by the barrier structure 103. As a result, the power supply trace 104 can pass through the barrier structure 103 into the region enclosed by the barrier structure 103. The portion of the barrier structure 103 for the power supply trace 104 to pass through may also be referred to as an inlet (port).

Combined with FIG. 1 and FIG. 2, the barrier structure 103 may include a first barrier dam 1031, a second barrier dam 1032, and a third barrier dam 1033. The first barrier dam 1031, the second barrier dam 1032, and the third barrier dam 1033 are disposed sequentially in a direction away from the display region 101a. Moreover, there is a gap between the adjacent barrier dams in the first barrier dam 1031, the second barrier dam 1032, and the third barrier dam 1033.

In some embodiments, the through-slot region 105a may be disposed on a side of the third barrier dam 1033 away from the display region 101a, and may also be disposed between the adjacent barrier dams. Two through-slot regions 105a are designed in FIG. 2, where one through-slot region 105a is disposed on a side of the third barrier dam 1033 away from the display region 101a, and the other through-slot region 105a is disposed between the second barrier dam 1032 and the third barrier dam 1033. Moreover, the through-slot region 105a is not designed between the first barrier dam 1031 and the second barrier dam 1032, and the through-slot region 105a between the second barrier dam 1032 and the third barrier dam 1033 is disposed only in the region where the first power supply signal trace is located, and not in the region where the second power supply signal trace is located. Through this design, the cathode layer and the barrier dam can overlap, which is convenient for realizing the narrow bezel of the display panel.

It is to be noted that the through-slot region 105a may be designed both between the first barrier dam 1031 and the second barrier dam 1032, and between the second barrier dam 1032 and the third barrier dam 1033.

In the embodiments of the present disclosure, each of the barrier dams in the barrier structure 103 includes at least one of the organic film layers in the display panel. The organic film layer in the display panel 10 includes a third organic film layer, a second organic film layer, and a first organic film layer. In addition, the organic film layer in the display panel 10 also includes a pixel definition layer, a support layer, and the like.

One of the first organic film layer, the second organic film layer, and the third organic film layer is disposed in a region of the barrier structure 103 where any barrier dam is adjacent and not provided with the through-slot region 105a. That is, either a through-slot region 105a or an organic film layer is provided between adjacent barrier dams or the position next to a barrier dam.

In some embodiments, the heights of the first barrier dam 1031, the second barrier dam 1032, and the third barrier dam 1033 may be sequentially increased in a direction away from the display region 101a. That is, the height of the first barrier dam 1031 is less than the height of the second barrier dam 1032, and the height of the second barrier dam 1032 is less than the height of the third barrier dam 1033. Alternatively, the heights of the first barrier dam 1031, the second barrier dam 1032, and the third barrier dam 1033 may be equal, which is not limited in the embodiments of the present disclosure.

In the embodiments of the present disclosure, the display panel 10 also includes an encapsulation film layer (not shown in the drawings) for encapsulating the display region 101a. The encapsulation film layer may include a first film layer, a second film layer, and a third film layer that are stacked in a direction away from the base substrate 101.

In some embodiments, the first film layer and the third film layer may be made of an inorganic material, and the second film layer may be made of an organic material. For example, the first film layer and the third film layer may be made of one or more inorganic oxides such as silicon nitride (SiNx), silicon oxide (SiOx), and silicon nitride oxide (SiOxNy). The second film layer may be made of a resin material. The resin may be a thermoplastic resin or a thermosetting resin, the thermoplastic resin may include an acrylic (PMMA) resin, and the thermosetting resin may include an epoxy resin.

It is noted that the second film layer may be disposed in the region enclosed by the barrier structure 103, and the first film layer and the third film layer may cover the region enclosed by the barrier structure 103 and cover the barrier structure 103. That is, orthographic projections of the first film layer and the third film layer on the base substrate 101 may be disposed on a side of the barrier structure 103 away from the display region 101a, i.e., disposed in the first target region m of the power supply trace 104.

As a result, the third trace layer of the power supply trace 104 disposed in the first target region m is etched to avoid the power supply trace 104 from being in an I-shaped, and thus to avoid the first film layer and the third film layer of the encapsulated film layer to be cracked in the first target region m.

In some embodiments, the second film layer may be prepared using an ink jet printing (IJP). The first film layer and the third film layer may be prepared using a chemical vapor deposition (CVD).

In the embodiments of the present disclosure, in the region of the power supply trace 104 that is covered by the organic film layer in the display panel 10, side edges of the third material layer a3, the second material layer a2, and the first material layer a1 are flat side edges, and the flat side edges are inclined relative to a carrying surface of the base substrate 101. The orthographic projection of the third material layer a3 on the base substrate 101 is within the orthographic projection of the second material layer a2 on the base substrate 101, and the orthographic projection of the second material layer a2 on the base substrate 101 is within the orthographic projection of the first material layer a1 on the base substrate 101.

In summary, the embodiments of the present disclosure provide a display panel. In the display panel, a first trace layer of a power supply trace has a first target region exposed by a through-slot region of a first organic film layer, and an orthographic projection of a third material layer of the first trace layer in the first target region is within an orthographic projection of the second material layer on the base substrate. An orthographic projection of the second material layer of the first trace layer in the first target region on the base substrate is within an orthographic projection of the first material layer on the base substrate. As a result, the subsequent formation of an encapsulation film layer of the display panel can be prevented from generating cracks in the first target region, and thus water and oxygen can be prevented from intruding into the display region along the intrusion channel generated by the cracks. The solution of the embodiments of the present application can ensure the light-emitting effect of the pixel units in the display region, avoid the occurrence of black-spot defects in the display region, have a higher yield of the display panel, and have a better display effect of the display panel.

FIG. 13 is a flowchart of a method for preparing a display panel according to some embodiments of the present disclosure. Referring to FIG. 13, the method includes the following steps.
In step S101, a base substrate is provided.

Referring to FIG. 3, the base substrate 101 has a display region 101a and a peripheral region 101b surrounding the display region 101a.
In step S102, a plurality of pixel units, a barrier structure, and at least one initial power supply trace are formed on a side of the base substrate.

The plurality of pixel units 102 are disposed in the display region 101a, the barrier structure 103 surrounds the display region 101a, and each initial power supply trace is configured to receive a power supply signal and is connected to the plurality of pixel units 102 for providing a power supply signal to the plurality of pixel units 102. The initial power supply trace includes at least a first initial trace layer, the first initial trace layer including a first material layer a1, a second material layer a2, and a third material layer a3 that are stacked sequentially in a direction away from the base substrate 101.

In some embodiments, the material of the first material layer a1 is the same as the material of the third material layer a3, and the material of the second material layer a2 is different from the material of the first material layer a1 and the third material layer a3.
In step S103, an initial organic film layer is formed on a side of the initial power supply trace away from the base substrate.

In the embodiments of the present disclosure, the initial organic film layer is provided with at least one through-slot region 105a. An orthographic projection of the through-slot region 105a on the base substrate 101 and an orthographic projection of the barrier structure 103 on the base substrate 101 are adjacent. The through-slot region 105a is configured to expose a first target region m of the initial power supply trace.
In step S104, a first trace layer of at least one power supply trace and a first organic film layer are acquired by etching, using an etching process, a third material layer of the first initial trace layer of the at least one initial power supply trace in the first target region and etching the initial organic film layer.

Referring to FIG. 11, an orthographic projection of the third material layer a3 of the first trace layer of the power supply trace 104 disposed in the first target region m on the base substrate 101 is within an orthographic projection of the second material layer a2 on the base substrate 101, and an orthographic projection of the second material layer a2 of the first trace layer of the power supply trace 104 disposed in the first target region m on the base substrate 101 is within an orthographic projection of the first material layer a1 on the base substrate 101.

In summary, the embodiments of the present disclosure provide a method for preparing a display panel. In the method, a first trace layer of a power supply trace in the display panel has a first target region exposed by a through-slot region of a first organic film layer, and an orthographic projection of a third material layer of the first trace layer in the first target region is within an orthographic projection of the second material layer on the base substrate. An orthographic projection of the second material layer of the first trace layer in the first target region on the base substrate is within an orthographic projection of the first material layer on the base substrate. As a result, the subsequent formation of an encapsulation film layer of the display panel can be prevented from generating cracks in the first target region, and thus water and oxygen can be prevented from intruding into the display region along the intrusion channel generated by the cracks. The solution of the embodiments of the present application can ensure the light-emitting effect of the pixel units in the display region, avoid the occurrence of black-spot defects in the display region, have a higher yield of the display panel, and have a better display effect of the display panel.

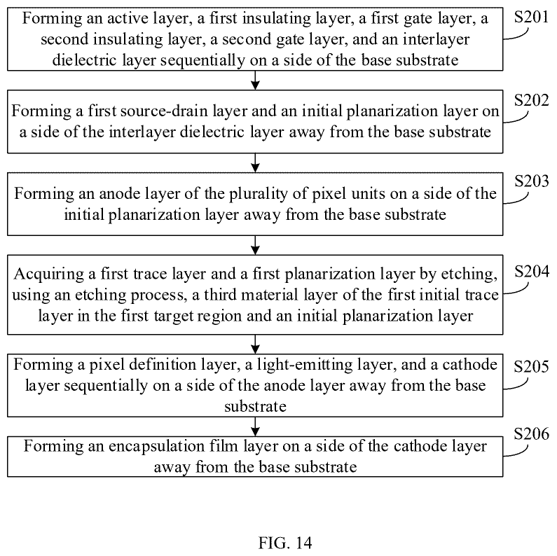

In a first implementation, FIG. 14 is a flowchart of another method for preparing a display panel according to some embodiments of the present disclosure. Taking the power supply trace 104 including a first trace layer as an example, referring to FIG. 14, the method includes the following steps.
In step S201, an active layer, a first insulating layer, a first gate layer, a second insulating layer, a second gate layer, and an interlayer dielectric layer are formed sequentially on a side of the base substrate.

In the embodiments of the present disclosure, the active layer includes a plurality of active patterns, and each active pattern may be used to form one thin film transistor in a pixel circuit included in the pixel unit 102. The first insulating layer is used to insulate the active layer and the first gate layer. The first gate layer includes a plurality of first gate patterns, an orthographic projection of each first gate pattern on the base substrate 101 partially overlaps an orthographic projection of an active pattern on the base substrate 101, and the overlapping region may be a channel of the thin film transistor. The second insulating layer is used to insulate the first gate layer from the second gate layer. The second gate layer includes a plurality of second gate patterns, and each second gate pattern may be used to form a plate of a storage capacitor in a pixel circuit. The interlayer dielectric layer is used to insulate the second gate layer from a first source-drain layer formed subsequently.
In step S202, a first source-drain layer and an initial planarization layer are formed on a side of the interlayer dielectric layer away from the base substrate.

In the embodiments of the present disclosure, the first source-drain layer includes at least the first trace layer of the power supply trace 104. The first trace layer includes a first material layer a1, a second material layer a2, and a third material layer a3 that are stacked sequentially in a direction away from the base substrate 101.

In some embodiments, the materials of the first material layer a1 and the third material layer a3 may both be titanium (Ti), and the material of the second material layer a2 may be aluminum (Al). That is, the first trace layer may be a triple-stacked layer structure of Ti/Al/Ti.

In the embodiments of the present disclosure, the initial planarization layer (the initial organic film layer) is provided with at least one through-slot region 105a, which is used to expose a first target region m of the first trace layer. Moreover, the initial planarization layer also includes a pattern for forming a barrier structure 103 in the display panel 10, for example, the initial planarization layer includes at least one annular pattern surrounding the display region 101a, the annular pattern is used to form one barrier dam in the barrier structure 103.

The through-slot region 105a and the annular pattern used to form one barrier dam in the barrier structure 103 are provided adjacent to each other, i.e., the through-slot region 105a and the barrier structure 103 are provided adjacent to each other.
In step S203, an anode layer of the plurality of pixel units is formed on a side of the initial planarization layer away from the base substrate.

In the embodiments of the present disclosure, the process of forming the anode layer includes forming an anode film on the side of the initial planarization layer away from the base substrate 101, and forming the anode layer of the plurality of pixel units 102 by processing the anode film using a patterning process. The process of the patterning process includes photoresist coating, exposure, developing, etching, and removing the photoresist.

The developer used in the developing process for preparing the anode layer affects the first target region m of the first trace layer and has a greater effect on the second material layer a2 of the first trace layer.

For example, before forming the anode layer, a first boundary a11 of a first material layer a1 of the first initial trace layer disposed in the first target region m, a second boundary a21 of a second material layer a2, and a third boundary a31 of the third material layer a3 are collinear. After forming the anode layer, the developer used for preparing the anode layer can side-etch the second material layer a2. An orthographic projection of the second material layer a2 of the first initial trace layer in the first target region m on the base substrate 101 is within an orthographic projection of the third material layer a3 on the base substrate 101, and the first boundary a11 of the first material layer a1 of the first initial trace layer in the first target region m and the third boundary a31 of the third material layer a3 are collinear. That is, after forming the anode layer, the first trace layer is in an I-shaped structure. The first boundary a11, the second boundary a21, and the third boundary a31 all extend in the first direction X.

As the first trace layer needs to be subsequently etched, in order to facilitate the distinction between the first trace layer before etching and after etching, subsequently, the first trace layer before etching is referred to as the first initial trace layer, and the first trace layer after etching is referred to as the first trace layer.
In step S204, a first trace layer and a first planarization layer are acquired by etching, using an etching process, a third material layer of the first initial trace layer in the first target region and an initial planarization layer.

In the embodiments of the present disclosure, as the portion of the first initial trace layer disposed in the first target region m is exposed and is in an I-shaped structure due to the influence of the developer of the anode layer in the above step S203, an etching process may be used to etch the third material layer a3 of the first initial trace layer disposed in the first target region m, and thus obtain the first trace layer. The process may be referred to as a Top Ti Etch (TTE) process.

Referring to FIG. 11, in the first trace layer obtained by the etching process, an orthographic projection of the third material layer a3 in the first target region m on the base substrate 101 is within an orthographic projection of the second material layer a2 in the first target region m on the base substrate 101. That is, the I-shaped structure of the first initial trace layer can be eliminated, such that the final first trace layer is in a step structure.

It is to be noted that in the process of etching the third material layer a3 in the first target region m, in order to ensure sufficient etching of the third material layer a3, a portion of the initial planarization layer may also be etched to obtain the first planarization layer ultimately formed (the first planarization layer is the first organic film layer 105). Moreover, the formed first planarization layer is provided with a groove region 105b, and the thickness of the portion of the first planarization layer disposed in the groove region 105b is less than the thickness of the portion disposed in the other regions.

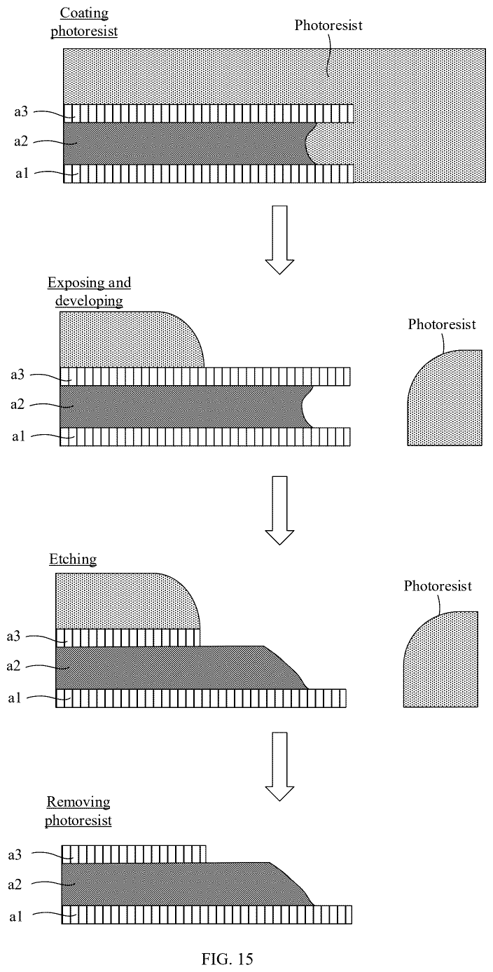

Referring to FIG. 15, the process of the etching process includes coating a photoresist on a side, away from the base substrate, of the initial organic film layer and the first initial trace layer in the first target region m; exposing the photoresist using a mask; developing the photoresist using a developer to remove an exposed portion of the photoresist; removing, using an etching process, a portion of the third material layer of the first initial trace layer in the first target region and the initial organic film layer that is not protected by the photoresist; and removing the remaining photoresist.

In the embodiments of the present disclosure, referring to FIG. 2 and FIG. 7, the mask has a plurality of mask openings, each of which has a first mask boundary extending in the first direction X. The first mask boundary is configured to form a third boundary of the first material layer a3 that is etched, an orthographic projection of the first mask boundary on the base substrate 101 is within the orthographic projection of the first material layer a1 on the base substrate 101. In addition, the distance between the first mask boundary and the first boundary a11 in a second direction Y is greater than 3 micrometers. Thus, the distance between the third boundary a13 and the first boundary a11 in the second direction Y can be greater than 3 μm.

Moreover, the first mask boundary is also configured to form a first groove boundary 105b1 of the groove region 105b of the first organic film layer 105 that is etched. The first groove boundary 105b1 is close to the first trace layer of the power supply trace 104 and extends in the first direction X. Referring to FIG. 11, the thickness of the first organic film layer 105 in the groove region 105b is less than the thickness of the first organic film layer 105 in other regions except the groove region 105b. The groove region 105b is configured to cover a second target region n of the power supply trace 104. The second target region n and the first target region m are adjacent in the first direction X.

The mask opening also has a second mask boundary extending in the second direction Y. The through-slot region 105a is disposed on a side of the second mask boundary, and the second mask boundary is configured to form a second groove boundary 105b2 that is disposed in a groove region 105b of the first organic film layer 105 away from the through-slot region 105a and extends in the second direction Y. The groove region 105b also has a third groove boundary 105b3 adjacent to the through-slot region 105a and extending in the second direction Y. The distance, in the first direction X, between the second groove boundary 105b2 and the third groove boundary 105b3 is greater than 3 μm.
In step S205, a pixel definition layer, a light-emitting layer, and a cathode layer are formed sequentially on a side of the anode layer away from the base substrate.

In the embodiments of the present disclosure, the pixel definition layer may be provided with a plurality of hollowed-out regions, and each hollowed-out region may be used to expose one anode pattern in the anode layer. The process of preparing the pixel definition layer includes forming a pixel definition film on a side of the anode layer away from the base substrate 101, and processing the pixel definition film using a patterning process to obtain the pixel definition layer.

In the case that the third material layer a3 in the first target region m (the first trace layer is in an I-shaped structure) is not etched using the etching process, there is pixel definition material remaining within the I-shaped structure after the pixel definition layer is prepared. Usually, the pixel definition material is an organic material (e.g., polyimide PI), and thus the pixel definition material can adsorb water and oxygen, which may cause some effect on the display of the display panel 10.

However, the solution of the embodiments of the present disclosure has eliminated the I-shaped structure of the first trace layer by the above step S204, such that after the pixel definition layer is prepared, the pixel definition material usually does not remain at the disposition of the first trace layer, and thus does not have an effect on the display of the display panel 10.

After the pixel definition layer is prepared, the light-emitting layer and the cathode layer may be prepared sequentially, thereby completing the preparation of the plurality of pixel units 102 and realizing the display of the display panel 10. Generally, the cathode layer of the plurality of pixel units 102 may be a common film layer, and the cathode layer may be disposed in the peripheral region 101b in addition to the display region 101a. In addition, the cathode layer is disposed at a boundary of the peripheral region 101b and on a side of the through-slot region 105a close to the display region 101a, so as to avoid a short circuit caused by the cathode layer being directly connected to the power supply traces 104 of different signals through the through-slot region 105a.
In step S206, an encapsulation film layer is formed on a side of the cathode layer away from the base substrate.

In the embodiments of the present disclosure, the encapsulation film layer may include a first film layer, a second film layer, and a third film layer that are stacked in a direction away from the base substrate 101.

In some embodiments, the first film layer and the third film layer may be made of an inorganic material, and the second film layer may be made of an organic material. For example, the first film layer and the third film layer may be made of one or more inorganic oxides such as SiNx (silicon nitride), SiOx (silicon oxide), and SiOxNy (silicon nitride oxide). The second film layer may be made of a resin material. The resin may be a thermoplastic resin or a thermoplastic resin, the thermoplastic resin may include an acrylic (PMMA) resin, and the thermosetting resin may include an epoxy resin.

It is noted that the second film layer may be disposed in the region enclosed by the barrier structure 103, and the first film layer and the third film layer may cover the region enclosed by the barrier structure 103 and cover the barrier structure 103. That is, orthographic projections of the first film layer and the third film layer on the base substrate 101 may be disposed on a side of the barrier structure 103 away from the display region 101a, i.e., disposed in the first target region m of the first trace layer.

As a result, the third trace layer of the first initial trace layer disposed in the first target region m is etched to avoid the final formed first trace layer to be in an I-shaped structure, and thus to avoid the first film layer and the third film layer of the encapsulated film layer to be cracked in the first target region m.

In some embodiments, the second film layer may be prepared using an IJP. The first film layer and the third film layer may be prepared using a CVD.

As the above step S204 has removed the I-shaped structure of the first trace layer, even if the first film layer and the third film layer of the encapsulation film layer cover the first target region m, no fracture will occur due to the presence of the I-shaped structure, and the step structure of the first target region m can be climbed layer by layer, thereby avoiding the formation of an intrusion channel for water and oxygen, and avoiding the occurrence of black-spot defects in the display region 101a.

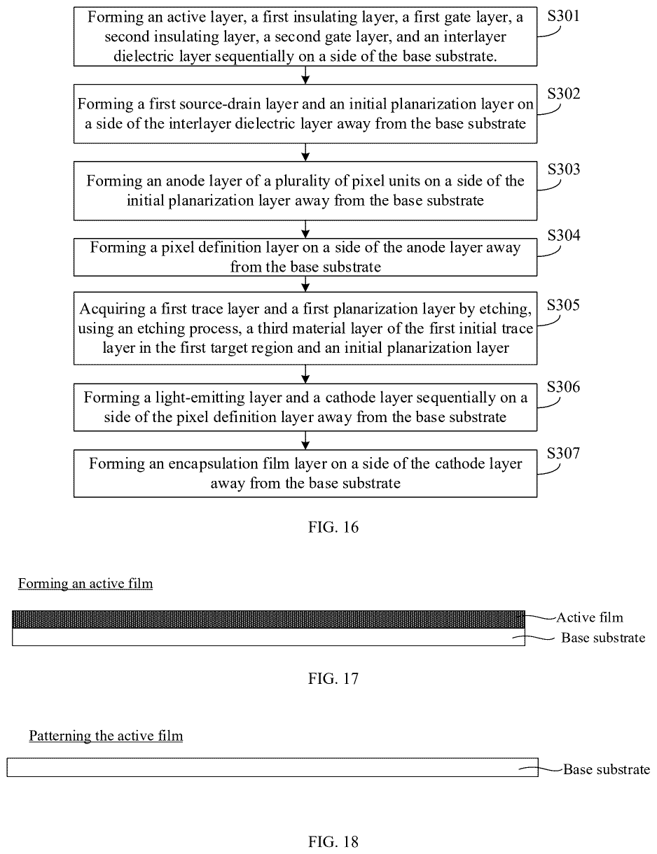

In a second implementation, FIG. 16 is a flowchart of yet another method for preparing a display panel according to some embodiments of the present disclosure. Taking the power supply trace 104 including a first trace layer as an example, referring to FIG. 16, the method includes the following steps.
In step S301, an active layer, a first insulating layer, a first gate layer, a second insulating layer, a second gate layer, and an interlayer dielectric layer are formed sequentially on a side of the base substrate.

In the embodiments of the present disclosure, the specific process of step S301 can be referred to the relevant description in step S201 above, and the embodiments of the present disclosure will not be repeated herein.
In step S302, a first source-drain layer and an initial planarization layer are formed on a side of the interlayer dielectric layer away from the base substrate.

In the embodiments of the present disclosure, the specific process of step S302 can be referred to the relevant description in step S202 above, and the embodiments of the present disclosure will not be repeated herein.
In step S303, an anode layer of a plurality of pixel units is formed on a side of the initial planarization layer away from the base substrate.

In the embodiments of the present disclosure, the specific process of step S303 can be referred to the relevant description in step S203 above, and the embodiments of the present disclosure will not be repeated herein.
In step S304, a pixel definition layer is formed on a side of the anode layer away from the base substrate.

In the embodiments of the present disclosure, the pixel definition layer may be provided with a plurality of hollowed-out regions, and each hollowed-out region may be used to expose one anode pattern in the anode layer. The process of preparing the pixel definition layer includes forming a pixel definition film on a side of the anode layer away from the base substrate 101, and processing the pixel definition film using a patterning process to obtain the pixel definition layer.

After the anode layer is prepared, the third material layer a3 in the first target region m is not etched by the etching process, and thus the first trace layer is in an I-shaped structure. As a result, after the pixel definition layer is prepared, the first trace layer has an indented region, and a portion of the material of the pixel definition layer is disposed in the indented region (i.e., pixel definition material remains within the I-shaped structure). The indented region is a region where the first trace layer has a first material layer a1 and a third material layer a3 and does not have a second material layer a2.
In step S305, a first trace layer and a first planarization layer are acquired by etching, using an etching process, a third material layer of the first initial trace layer in the first target region and an initial planarization layer.

In the embodiments of the present disclosure, as the portion of the first initial trace layer disposed in the first target region m is exposed and is in an I-shaped structure due to the influence of the developer of the anode layer in the above step S303, and the pixel definition material remains within the I-shaped structure in the above step S304, in order to eliminate the I-shaped structure and remove the remaining pixel definition material, an etching process may be used to etch the third material layer a3 of the first initial trace layer disposed in the first target region m, and thus obtain the first trace layer. The process may be referred to as a TTE process.

Referring to FIG. 11, in the first trace layer obtained by the etching process, an orthographic projection of the third material layer a3 in the first target region m on the base substrate 101 is within an orthographic projection of the second material layer a2 in the first target region m on the base substrate 101. That is, the I-shaped structure of the first initial trace layer can be eliminated, such that the final first trace layer is in a step structure. Moreover, the pixel definition material remaining in the I-shaped structure can be removed.

It is to be noted that in the process of etching the third material layer a3 in the first target region m, in order to ensure sufficient etching of the third material layer a3, a portion of the initial planarization layer may also be etched to obtain the first planarization layer ultimately formed. Moreover, the formed first planarization layer is provided with a groove region 105b, and the thickness of the portion of the first planarization layer disposed in the groove region 105b is less than the thickness of the portion disposed in the other regions.

In addition, the specific process of the etching process can be referred to as step S204 above, and the embodiments of the present disclosure will not be repeated herein.
In step S306, a light-emitting layer and a cathode layer are formed sequentially on a side of the pixel definition layer away from the base substrate.

After the pixel definition layer is prepared, the light-emitting layer and the cathode layer may be prepared sequentially, thereby completing the preparation of the plurality of pixel units 102 and realizing the display of the display panel 10. Generally, the cathode layer of the plurality of pixel units 102 may be a common film layer, and the cathode layer may be disposed in the peripheral region 101b in addition to the display region 101a. In addition, the cathode layer is disposed at a boundary of the peripheral region 101b and on a side of the through-slot region 105a close to the display region 101a, so as to avoid a short circuit caused by the cathode layer being directly connected to the power supply traces 104 of different signals through the through-slot region 105a.
In step S307, an encapsulation film layer is formed on a side of the cathode layer away from the base substrate.

In the embodiments of the present disclosure, the specific process of step S307 can be referred to the relevant description in step S206 above, and the embodiments of the present disclosure will not be repeated herein.

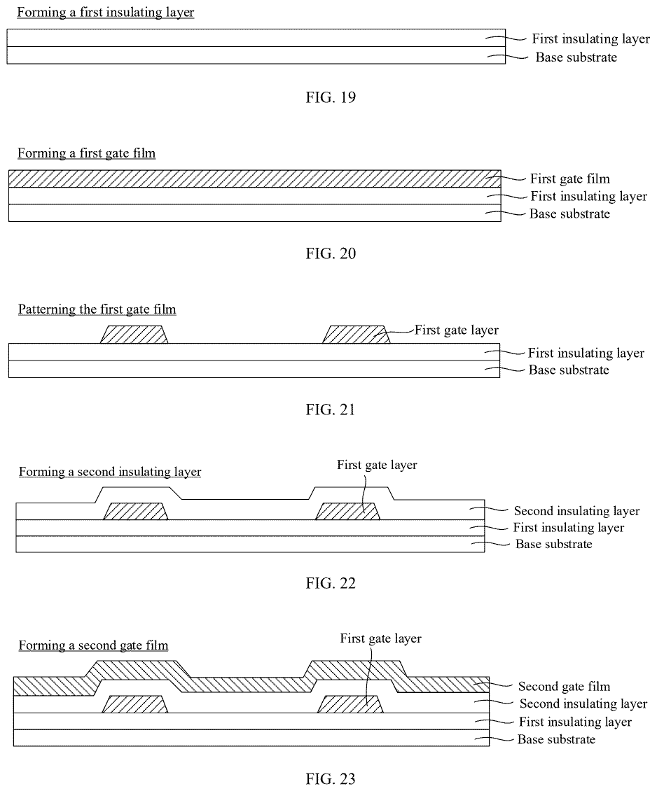

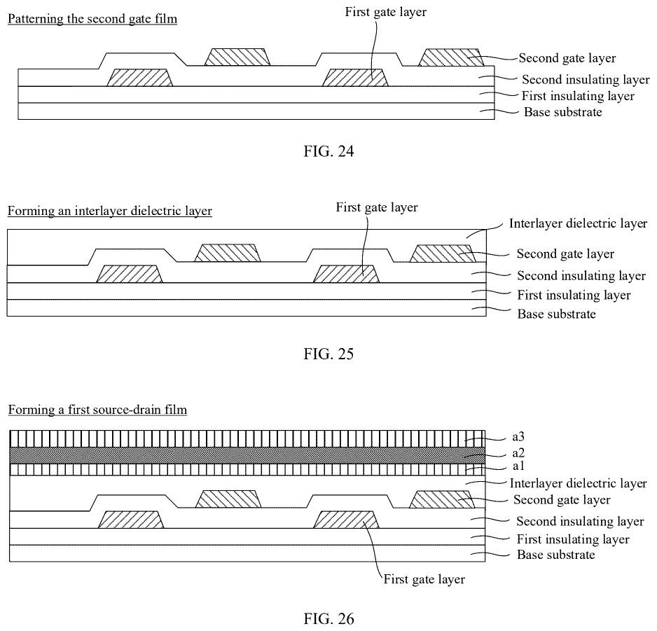

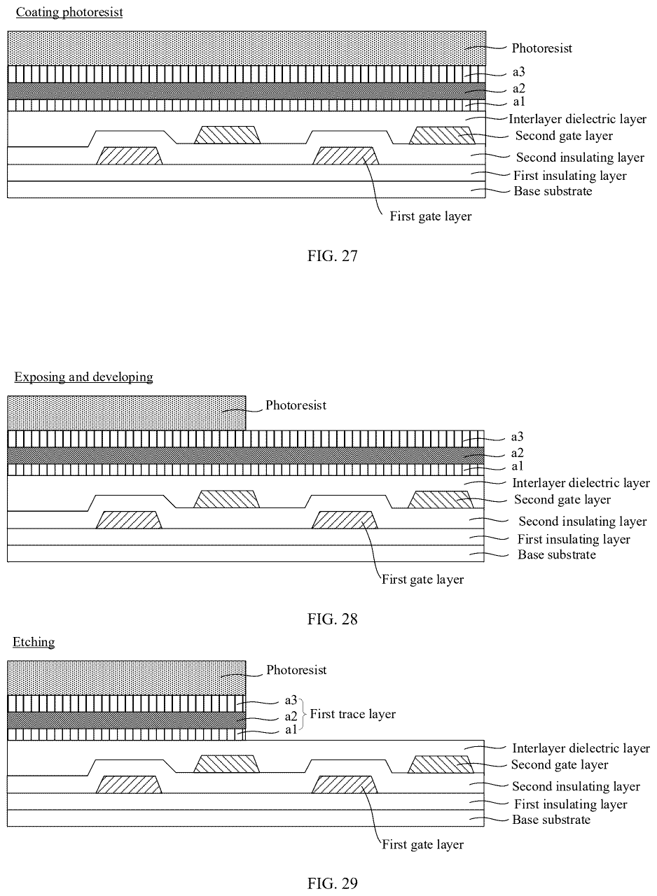

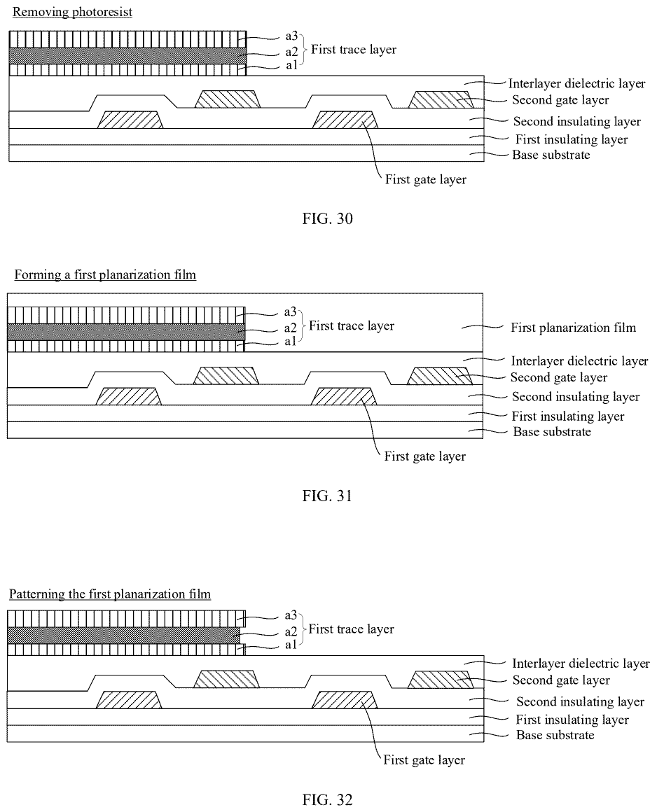

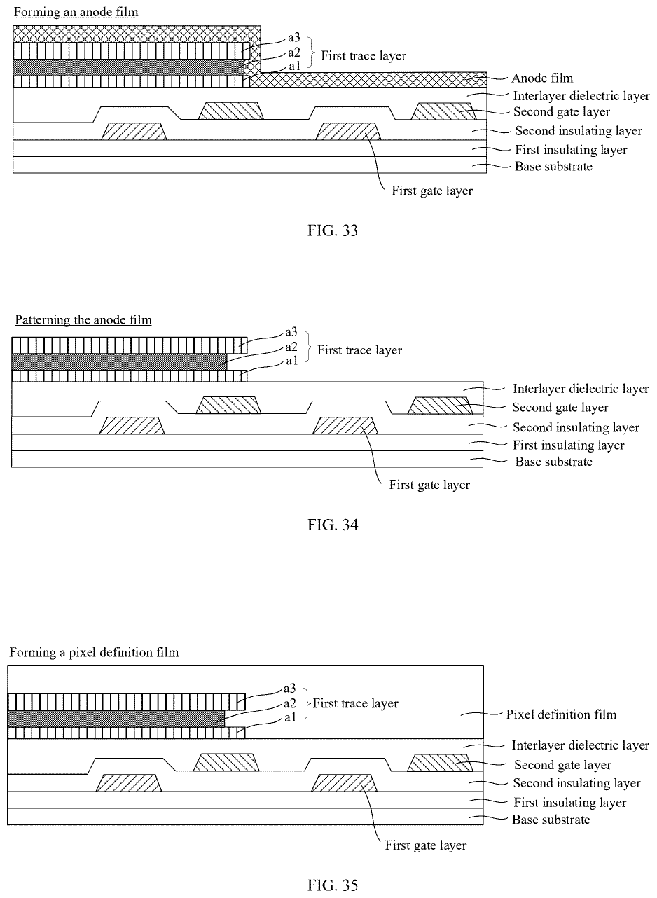

In the first implementation and the second implementation described above, a cross-sectional view in the DD direction in FIG. 7 is specifically described as an example. Referring to FIGS. 17 to 34, the steps include forming an active film; patterning the active film (coating a photoresist, exposing, developing, etching, and removing the photoresist); forming a first insulating layer; forming a first gate film; patterning the first gate film (coating a photoresist, exposing, developing, etching, and removing the photoresist); forming a second insulating layer; forming a second gate film; patterning the second gate film (coating a photoresist, exposing, developing, etching, and removing the photoresist); forming an interlayer dielectric layer; forming a first source-drain film (the first source-drain film is used to form the source and drain of a thin-film transistor as and the first trace layer of the power supply trace), wherein the first source-drain film includes a first material layer, a second material layer, and a third material layer; coating a photoresist on a side of the first source-drain film away from the base; exposing the photoresist using a mask, and developing the photoresist using a developer; etching the first source-drain film to form a first trace layer; removing the remaining photoresist; forming a first planarization film; and patterning the first planarization film (coating a photoresist, exposing, developing, etching, and removing the photoresist) to form a through-slot region of the first planarization layer, so as to expose a first target region of the first trace layer. As can be seen in FIG. 32, after patterning the first planarization film, affected by the process, the second material layer a2 is internally etched relative to the first material layer a1 and the third material layer a3; and referring to FIG. 33, an anode film is formed; and the anode film is patterned (coating a photoresist, exposing, developing, etching, and removing the photoresist). As can be seen in FIG. 34, after patterning the anode film, affected by the process, the second material layer a2 is further internally etched relative to the first material layer a1 and the third material layer a3.

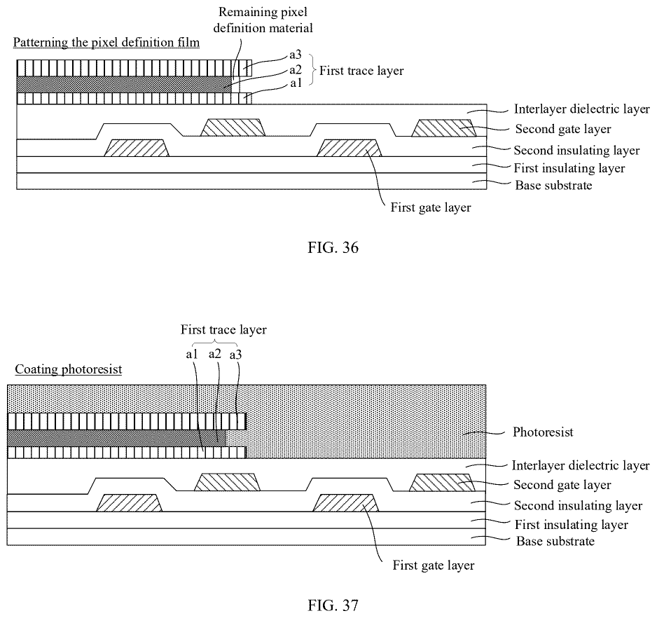

Referring to FIG. 35 and FIG. 36, after patterning the anode film, a pixel definition film is directly formed, and the pixel definition film is patterned, which results in the presence of remaining pixel definition material in the indented region of the second material layer a2 relative to the first material layer a1 and the third material layer a3. In the case that the third material layer a3 is not subsequently etched, the first trace layer is in an I-shaped structure and the remaining pixel definition material is present in the I-shaped structure. Therefore, cracks may occur in the subsequent encapsulated film at the location of the I-shaped structure, and an intrusion channel for water and oxygen is formed due to the presence of the remaining pixel definition material (organic material), which affects the yield of the pixel units in the display region.

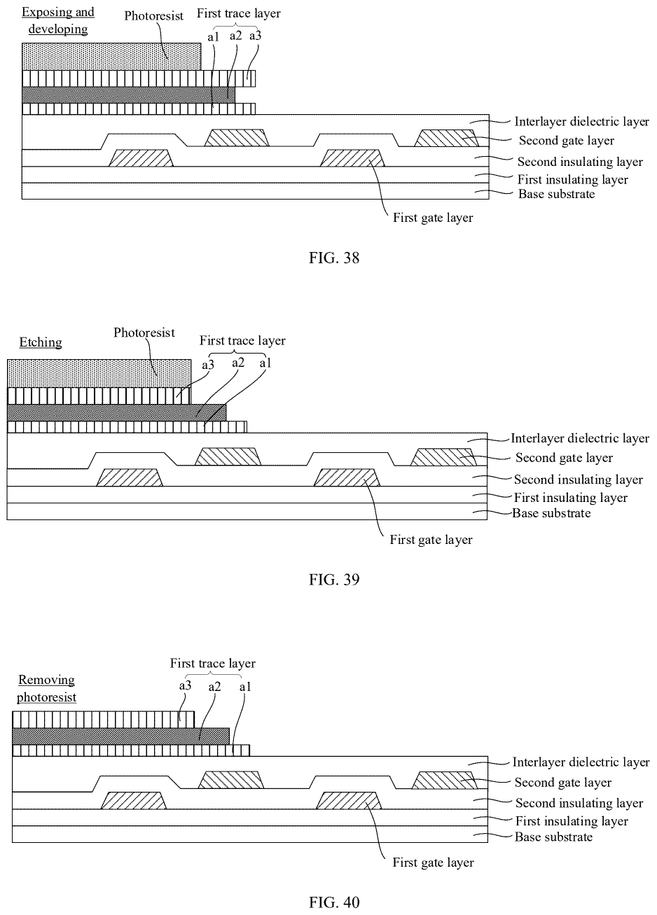

In the embodiments of the present disclosure, as an optional implementation, referring to FIGS. 37 to 40, after patterning the anode film, the third material layer a3 is etched to eliminate the I-shaped structure of the first trace layer. The steps include coating a photoresist; exposing the photoresist using a mask and developing the photoresist using a developer; etching the third material layer; and removing the remaining photoresist. In this way, the I-shaped structure of the first trace layer is eliminated, which in turn can avoid the remaining subsequent pixel definition material, prevent the subsequent encapsulation film from generating cracks, and ensure the yield of the pixel units in the display region.

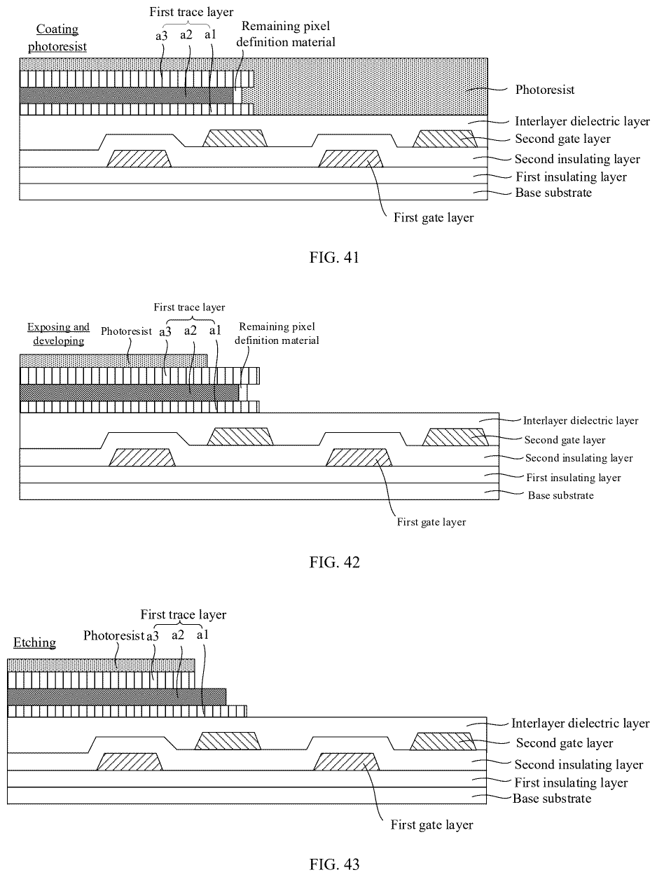

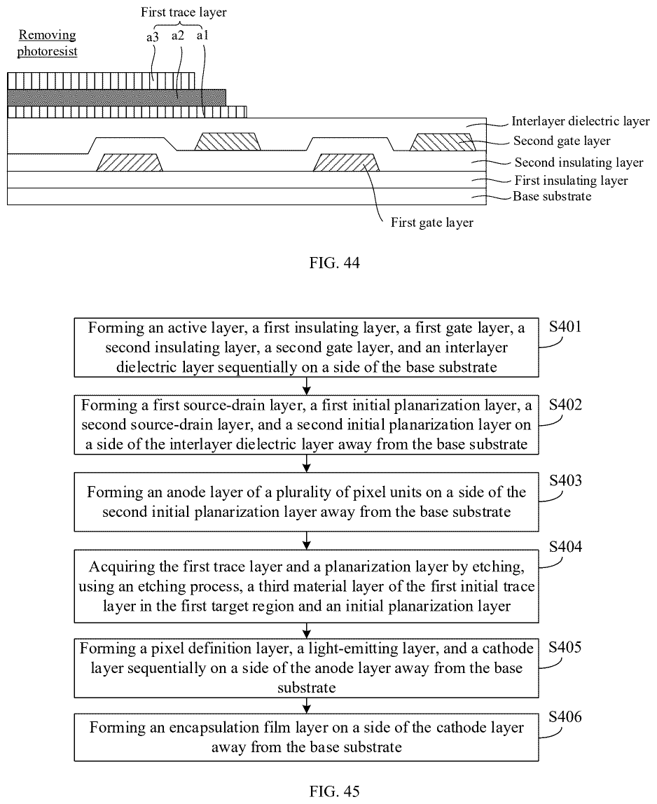

As another optional implementation, referring to FIGS. 41 to 44, after patterning the pixel definition film, the third material layer a3 is etched to eliminate the I-shaped structure of the first trace layer and to remove the remaining pixel definition material. The steps include coating a photoresist; exposing the photoresist using a mask and developing the photoresist using a developer; etching the third material layer; and removing the remaining photoresist. In this way, the I-shaped structure of the first trace layer is eliminated, the remaining pixel definition material can be removed, cracks in the subsequent encapsulation film are avoided, and the yield of the pixel units in the display region is ensured.

In a third implementation, FIG. 45 is a flowchart of a further method for preparing a display panel according to some embodiments of the present disclosure. Taking the power supply trace 104 including a first trace layer and a second trace layer as an example, referring to FIG. 45, the method includes the following steps.
In step S401, an active layer, a first insulating layer, a first gate layer, a second insulating layer, a second gate layer, and an interlayer dielectric layer are formed sequentially on a side of the base substrate.

In the embodiments of the present disclosure, the specific process of step S401 can be referred to the relevant description in step S201 above, and the embodiments of the present disclosure will not be repeated herein.
In step S402, a first source-drain layer, a first initial planarization layer, a second source-drain layer, and a second initial planarization layer are formed on a side of the interlayer dielectric layer away from the base substrate.

In the embodiments of the present disclosure, the first source-drain layer includes at least a second trace layer of the power supply trace 104. The second source-drain layer includes at least a first trace layer of the power supply trace 104. An orthographic projection of the first trace layer on the base substrate 101 covers an orthographic projection of the second trace layer on the base substrate 101. Both the first trace layer and the second trace layer include a first material layer a1, a second material layer a2, and a third material layer a3 that are stacked sequentially in a direction away from the base substrate 101.

In some embodiments, the materials of the first material layer a1 and the third material layer a3 may both be titanium (Ti), and the material of the second material layer a2 may be aluminum (Al). That is, both the first trace layer and the second trace layer may be a triple-stacked layer structure of Ti/Al/Ti.

In the embodiments of the present disclosure, the first initial planarization layer and the second initial planarization layer are provided with at least one through-slot region 105a. Moreover, as an orthographic projection of the first trace layer on the base substrate 101 covers an orthographic projection of the second trace layer on the base substrate 101, the through-slot region 105a may only expose the first target region m of the first trace layer, and not expose the second trace layer. In addition, the first initial planarization layer and the second initial planarization layer also include a pattern for forming the barrier structure 103 in the display panel 10, for example, both the first initial planarization layer and the second initial planarization layer include at least one annular pattern around the display region 101a, which is used to form one barrier dam in the barrier structure 103.

The through-slot region 105a and the annular pattern used to form one barrier dam in the barrier structure 103 are provided adjacent to each other, i.e., the through-slot region 105a and the barrier structure 103 are provided adjacent to each other.
In step S403, an anode layer of a plurality of pixel units is formed on a side of the second initial planarization layer away from the base substrate.

In the embodiments of the present disclosure, the process of forming the anode layer includes forming an anode film on the side of the second initial planarization layer away from the base substrate 101, and forming the anode layer of the plurality of pixel units 102 by processing the anode film using a patterning process. The process of the patterning process includes photoresist coating, exposure, developing, etching, and removing the photoresist.

The developer used in the developing process for preparing the anode layer affects the first target region m of the first trace layer and has a greater effect on the second material layer a2 of the first trace layer.

For example, before forming the anode layer, a first boundary a11 of a first material layer a1 of the first initial trace layer in the first target region m, a second boundary a21 of a second material layer a2, and a third boundary a31 of the third material layer a3 are collinear. After forming the anode layer, the developer used for preparing the anode layer can side-etch the second material layer a2. An orthographic projection of the second material layer a2 of the first initial trace layer in the first target region m on the base substrate 101 is within an orthographic projection of the third material layer a3 on the base substrate 101, and the first boundary a11 of the first material layer a1 of the first initial trace layer in the first target region m and the third boundary a31 of the third material layer a3 are collinear. That is, after forming the anode layer, the first trace layer is in an I-shaped structure. The first boundary a11, the second boundary a21, and the third boundary a31 all extend in the first direction X.

As the first trace layer needs to be subsequently etched, in order to facilitate the distinction between the first trace layer before etching and after etching, subsequently, the first trace layer before etching is referred to as the first initial trace layer, and the first trace layer after etching is referred to as the first trace layer. Moreover, the first planarization layer and the second planarization layer may be etched subsequently, and for ease of description subsequently, the first planarization layer and the second planarization layer before etching are collectively referred to as the initial planarization layer, and the first planarization layer and the second planarization layer after etching are collectively referred to as the planarization layer.
In step S404, the first trace layer and a planarization layer are acquired by etching, using an etching process, a third material layer of the first initial trace layer in the first target region and an initial planarization layer.

In the embodiments of the present disclosure, as the portion of the first initial trace layer disposed in the first target region m is exposed and is in an I-shaped structure due to the influence of the developer of the anode layer in the above step S403, an etching process may be used to etch the third material layer a3 of the first initial trace layer disposed in the first target region m, and thus obtain the first trace layer. The process may be referred to as a TTE process.

Referring to FIG. 11, in the first trace layer obtained by the etching process, an orthographic projection of the third material layer a3 in the first target region m on the base substrate 101 is within an orthographic projection of the second material layer a2 in the first target region m on the base substrate 101. That is, the I-shaped structure of the first initial trace layer can be eliminated, such that the final first trace layer is in a step structure.

It is to be noted that in the process of etching the third material layer a3 in the first target region m, in order to ensure sufficient etching of the third material layer a3, a portion of the initial planarization layer may also be etched to obtain the planarization layer ultimately formed. Moreover, the formed planarization layer is provided with a groove region 105b, and the thickness of the portion of the planarization layer disposed in the groove region 105b is less than the thickness of the portion disposed in the other regions.
In step S405, a pixel definition layer, a light-emitting layer, and a cathode layer are formed sequentially on a side of the anode layer away from the base substrate.

In the embodiments of the present disclosure, the specific process of step S405 can be referred to the relevant description in step S205 above, and the embodiments of the present disclosure will not be repeated herein.
In step S406, an encapsulation film layer is formed on a side of the cathode layer away from the base substrate.

In the embodiments of the present disclosure, the specific process of step S406 can be referred to the relevant description in step S206 above, and the embodiments of the present disclosure will not be repeated herein.

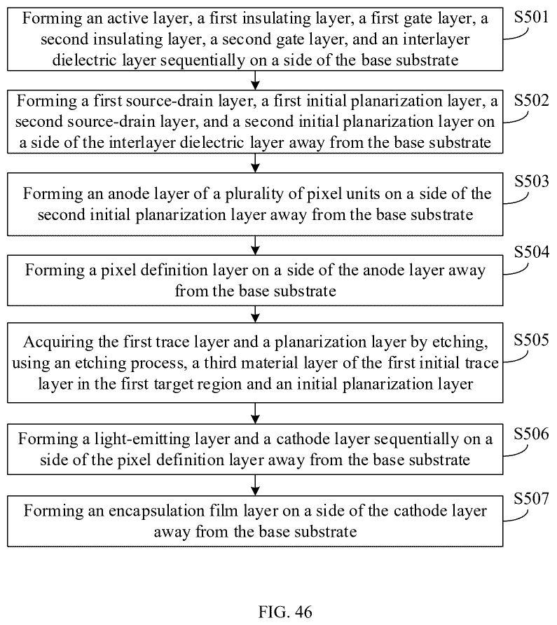

In a fourth implementation, FIG. 46 is a flowchart of a further method for preparing a display panel according to some embodiments of the present disclosure. Taking the power supply trace 104 including a first trace layer and a second trace layer as an example, referring to FIG. 46, the method includes the following steps.
In step S501, an active layer, a first insulating layer, a first gate layer, a second insulating layer, a second gate layer, and an interlayer dielectric layer are formed sequentially on a side of the base substrate.

In the embodiments of the present disclosure, the specific process of step S501 can be referred to the relevant description in step S201 above, and the embodiments of the present disclosure will not be repeated herein.
In step S502, a first source-drain layer, a first initial planarization layer, a second source-drain layer, and a second initial planarization layer are formed on a side of the interlayer dielectric layer away from the base substrate.

In the embodiments of the present disclosure, the specific process of step S502 can be referred to the relevant description in step S402 above, and the embodiments of the present disclosure will not be repeated herein.
In step S503, an anode layer of a plurality of pixel units is formed on a side of the second initial planarization layer away from the base substrate.

In the embodiments of the present disclosure, the specific process of step S503 can be referred to the relevant description in step S403 above, and the embodiments of the present disclosure will not be repeated herein.
In step S504, a pixel definition layer is formed on a side of the anode layer away from the base substrate.

In the embodiments of the present disclosure, the specific process of step S504 can be referred to the relevant description in step S304 above, and the embodiments of the present disclosure will not be repeated herein.
In step S505, the first trace layer and a planarization layer are acquired by etching, using an etching process, a third material layer of the first initial trace layer in the first target region and an initial planarization layer.

In the embodiments of the present disclosure, as the portion of the first initial trace layer disposed in the first target region m is exposed and is in an I-shaped structure due to the influence of the developer of the anode layer in the above step S503, and the pixel definition material remains within the I-shaped structure in the above step S504, in order to eliminate the I-shaped structure and remove the remaining pixel definition material, an etching process may be used to etch the third material layer a3 of the first initial trace layer disposed in the first target region m, and thus obtain the first trace layer. The process may be referred to as a TTE process.

Referring to FIG. 11, in the first trace layer obtained by the etching process, an orthographic projection of the third material layer a3 in the first target region m on the base substrate 101 is within an orthographic projection of the second material layer a2 in the first target region m on the base substrate 101. That is, the I-shaped structure of the first initial trace layer can be eliminated, such that the final first trace layer is in a step structure. Moreover, the pixel definition material remaining in the I-shaped structure can be removed.

It is to be noted that in the process of etching the third material layer a3 in the first target region m, in order to ensure sufficient etching of the third material layer a3, a portion of the initial planarization layer may also be etched to obtain the planarization layer ultimately formed. Moreover, the formed planarization layer is provided with a groove region 105b, and the thickness of the portion of the planarization layer disposed in the groove region 105b is less than the thickness of the portion disposed in the other regions.
In step S506, a light-emitting layer and a cathode layer are formed sequentially on a side of the pixel definition layer away from the base substrate.

In the embodiments of the present disclosure, the specific process of step S506 can be referred to the relevant description in step S306 above, and the embodiments of the present disclosure will not be repeated herein.
In step S507, an encapsulation film layer is formed on a side of the cathode layer away from the base substrate.

In the embodiments of the present disclosure, the specific process of step S507 can be referred to the relevant description in step S206 above, and the embodiments of the present disclosure will not be repeated herein.

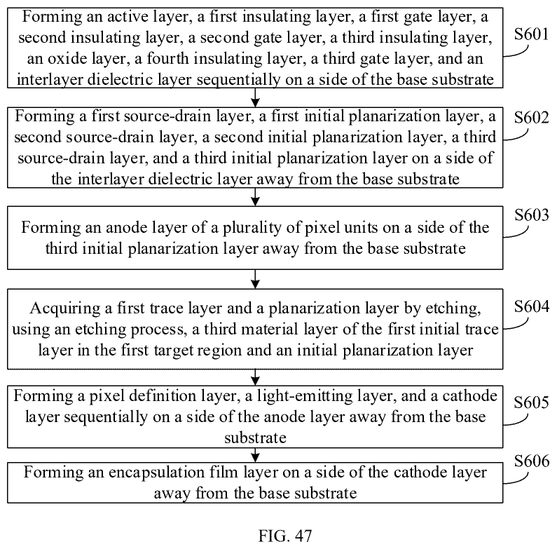

In a fifth implementation, FIG. 47 is a flowchart of a further method for preparing a display panel 10 according to some embodiments of the present disclosure. Taking the power supply trace 104 including a first trace layer, a second trace layer, and a third trace layer as an example, referring to FIG. 47, the method includes the following steps.
In step S601, an active layer, a first insulating layer, a first gate layer, a second insulating layer, a second gate layer, a third insulating layer, an oxide layer, a fourth insulating layer, a third gate layer, and an interlayer dielectric layer are formed sequentially on a side of the base substrate.

In the embodiments of the present disclosure, the active layer includes a plurality of active patterns, and each active pattern may be used to form one thin film transistor in a pixel circuit included in the pixel unit 102. The first insulating layer is used to insulate the active layer and the first gate layer. The first gate layer includes a plurality of first gate patterns, an orthographic projection of each first gate pattern on the base substrate 101 partially overlaps an orthographic projection of an active pattern on the base substrate 101, and the overlapping region may be a channel of the thin film transistor. The second insulating layer is used to insulate the first gate layer from the second gate layer. The second gate layer includes a plurality of second gate patterns and a plurality of third gate patterns, each of the second gate patterns may be used to form a plate of a storage capacitor in a pixel circuit, and each of the third gate patterns may be used to form a bottom gate of an oxide thin film transistor in the pixel circuit. The third insulating layer is used to insulate the second gate layer from the oxide layer. The oxide layer includes a plurality of oxide patterns, and each of the oxide patterns is used to form an oxide thin film transistor. The fourth insulating layer is used to insulate the oxide layer from the third gate layer. The third gate layer includes at least a plurality of fourth gate patterns, and each of the fourth gate patterns is used to form a top gate of the oxide thin film transistor. The interlayer dielectric layer is used to insulate the third gate layer from a first source-drain layer formed subsequently.
In step S602, a first source-drain layer, a first initial planarization layer, a second source-drain layer, a second initial planarization layer, a third source-drain layer, and a third initial planarization layer are formed on a side of the interlayer dielectric layer away from the base substrate.

In the embodiments of the present disclosure, the first source-drain layer includes at least a third trace layer of the power supply trace 104. The second source-drain layer includes at least a second trace layer of the power supply trace 104. The third source-drain layer includes at least a first trace layer of the power supply trace 104, an orthographic projection of the first trace layer on the base substrate 101 covers an orthographic projection of the second trace layer on the base substrate 101, and covers an orthographic projection of the third trace layer on the base substrate 101. The first trace layer, the second trace layer, and the third trace layer all include a first material layer a1, a second material layer a2, and a third material layer a3 that are stacked sequentially in a direction away from the base substrate 101.

In some embodiments, the materials of the first material layer a1 and the third material layer a3 may both be titanium (Ti), and the material of the second material layer a2 may be aluminum (Al). That is, the first trace layer, the second trace layer, and the third trace layer may all be a triple-stacked layer structure of Ti/Al/Ti.

In the embodiments of the present disclosure, the first initial planarization layer, the second initial planarization layer, and the third initial planarization layer are provided with at least one through-slot region 105a. In addition, as the orthographic projection of the first trace layer on the base substrate 101 covers the orthographic projections of the second trace layer and the third trace layer on the base substrate 101, the through-slot region 105a can only expose the first target region m of the first trace layer, and not expose the second trace layer and the third trace layer. Moreover, the first initial planarization layer, the second initial planarization layer, and the third initial planarization layer also include a pattern for forming the barrier structure 103 in the display panel 10, for example, the first initial planarization layer, the second initial planarization layer, and the third initial planarization layer all include at least one annular pattern surrounding the display region 101a, which is used to form one barrier dam in the barrier structure 103.

The through-slot region 105a and the annular pattern used to form one barrier dam in the barrier structure 103 are provided adjacent to each other, i.e., the through-slot region 105a and the barrier structure 103 are provided adjacent to each other.
In step S603, an anode layer of a plurality of pixel units is formed on a side of the third initial planarization layer away from the base substrate.

In the embodiments of the present disclosure, the process of forming the anode layer includes forming an anode film on the side of the third initial planarization layer away from the base substrate 101, and forming the anode layer of the plurality of pixel units 102 by processing the anode film using a patterning process. The process of the patterning process includes photoresist coating, exposure, developing, etching, and removing the photoresist.

The developer used in the developing process for preparing the anode layer affects the first target region m of the first trace layer and has a greater effect on the second material layer a2 of the first trace layer.

For example, before forming the anode layer, a first boundary a11 of a first material layer a1 of the first initial trace layer in the first target region m, a second boundary a21 of a second material layer a2, and a third boundary a31 of the third material layer a3 are collinear. After forming the anode layer, the developer used for preparing the anode layer can side-etch the second material layer a2. An orthographic projection of the second material layer a2 of the first initial trace layer in the first target region m on the base substrate 101 is within an orthographic projection of the third material layer a3 on the base substrate 101, and the first boundary a11 of the first material layer a1 of the first initial trace layer in the first target region m and the third boundary a31 of the third material layer a3 are collinear. That is, after forming the anode layer, the first trace layer is in an I-shaped structure. The first boundary a11, the second boundary a21, and the third boundary a31 all extend in the first direction X.

As the first trace layer needs to be subsequently etched, in order to facilitate the distinction between the first trace layer before etching and after etching, subsequently, the first trace layer before etching is referred to as the first initial trace layer, and the first trace layer after etching is referred to as the first trace layer. Moreover, the first planarization layer, the second planarization layer, and the third planarization layer may be etched subsequently, and for ease of description subsequently, the first planarization layer, the second planarization layer, and the third planarization layer before etching are collectively referred to as the initial planarization layer, and the first planarization layer, the second planarization layer, and the third planarization layer after etching are collectively referred to as the planarization layer.
In step S604, a first trace layer and a planarization layer are acquired by etching, using an etching process, a third material layer of the first initial trace layer in the first target region and an initial planarization layer.

In the embodiments of the present disclosure, the specific process of step S604 can be referred to the relevant description in step S404 above, and the embodiments of the present disclosure will not be repeated herein.
In step S605, a pixel definition layer, a light-emitting layer, and a cathode layer are formed sequentially on a side of the anode layer away from the base substrate.

In the embodiments of the present disclosure, the specific process of step S605 can be referred to the relevant description in step S205 above, and the embodiments of the present disclosure will not be repeated herein.
In step S606, an encapsulation film layer is formed on a side of the cathode layer away from the base substrate.

In the embodiments of the present disclosure, the specific process of step S606 can be referred to the relevant description in step S206 above, and the embodiments of the present disclosure will not be repeated herein.

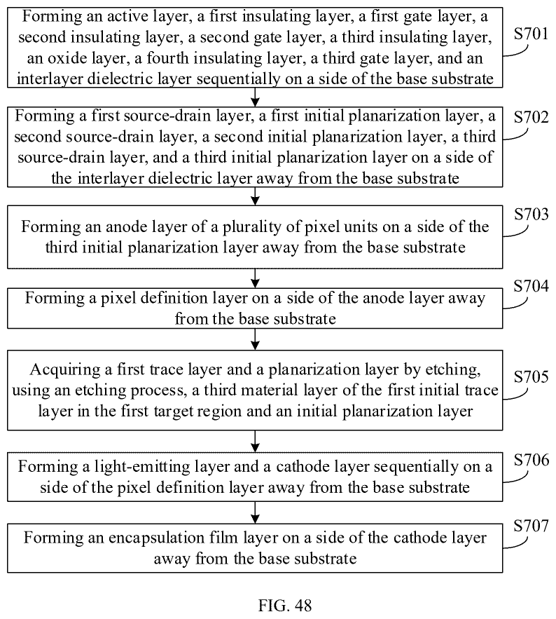

In a sixth implementation, FIG. 48 is a flowchart of a further method for preparing a display panel according to some embodiments of the present disclosure. Taking the power supply trace 104 including a first trace layer, a second trace layer, and a third trace layer as an example, referring to FIG. 48, the method includes the following steps.
In step S701, an active layer, a first insulating layer, a first gate layer, a second insulating layer, a second gate layer, a third insulating layer, an oxide layer, a fourth insulating layer, a third gate layer, and an interlayer dielectric layer are formed sequentially on a side of the base substrate.

In the embodiment of the present disclosure, the specific process of step S701 can be referred to the relevant description in step S601 above, and the embodiments of the present disclosure will not be repeated herein.
In step S702, a first source-drain layer, a first initial planarization layer, a second source-drain layer, a second initial planarization layer, a third source-drain layer, and a third initial planarization layer are formed on a side of the interlayer dielectric layer away from the base substrate.

In the embodiments of the present disclosure, the specific process of step S702 can be referred to the relevant description in step S602 above, and the embodiments of the present disclosure will not be repeated herein.
In step S703, an anode layer of a plurality of pixel units is formed on a side of the third initial planarization layer away from the base substrate.

In the embodiments of the present disclosure, the specific process of step S703 can be referred to the relevant description in step S603 above, and the embodiments of the present disclosure will not be repeated herein.
In step S704, a pixel definition layer is formed on a side of the anode layer away from the base substrate.

In the embodiments of the present disclosure, the specific process of step S704 can be referred to the relevant description in step S304 above, and the embodiments of the present disclosure will not be repeated herein.
In step S705, a first trace layer and a planarization layer are acquired by etching, using an etching process, a third material layer of the first initial trace layer in the first target region and an initial planarization layer.

In the embodiments of the present disclosure, the specific process of step S705 can be referred to the relevant description in step S505 above, and the embodiments of the present disclosure will not be repeated herein.
In step S706, a light-emitting layer and a cathode layer are formed sequentially on a side of the pixel definition layer away from the base substrate.

In the embodiments of the present disclosure, the specific process of step S706 can be referred to the relevant description in step S306 above, and the embodiments of the present disclosure will not be repeated herein.
In step S707, an encapsulation film layer is formed on a side of the cathode layer away from the base substrate.

In the embodiments of the present disclosure, the specific process of step S707 can be referred to the relevant description in step S206 above, and the embodiments of the present disclosure will not be repeated herein.

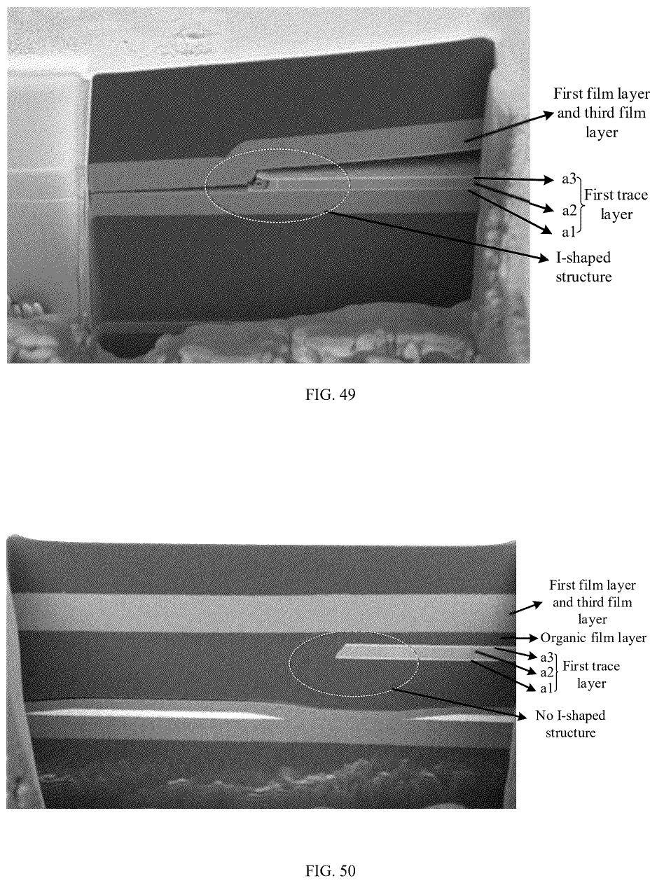

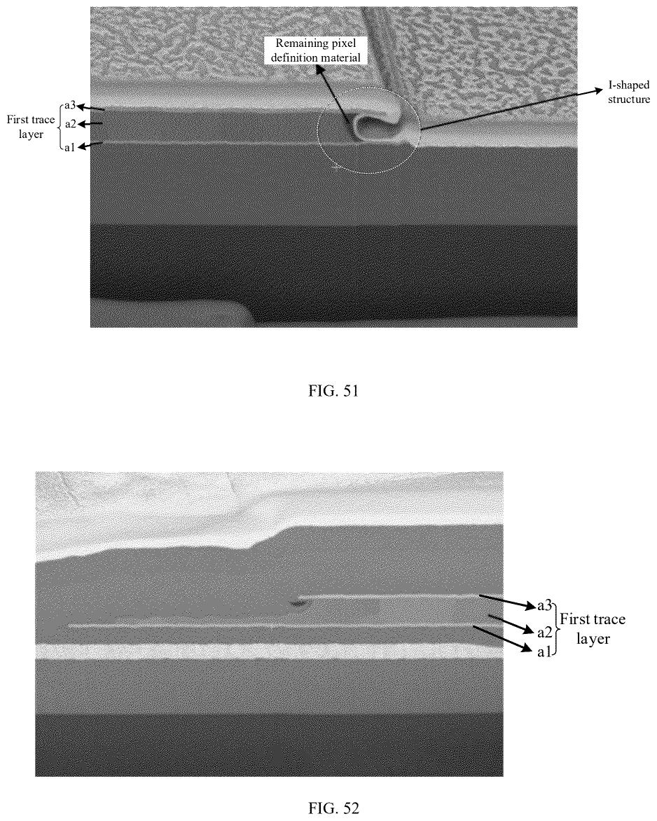

In the embodiments of the present disclosure, referring to FIG. 49 and FIG. 50, it can be seen that the region of the first trace layer that is not protected by the organic film layer (the first target region) is in an I-shaped structure, and the region that is protected by the organic film layer is not in an I-shaped structure. Moreover, referring to FIG. 51, after the pixel definition layer is prepared, the remaining pixel definition material is present within the I-shaped structure.

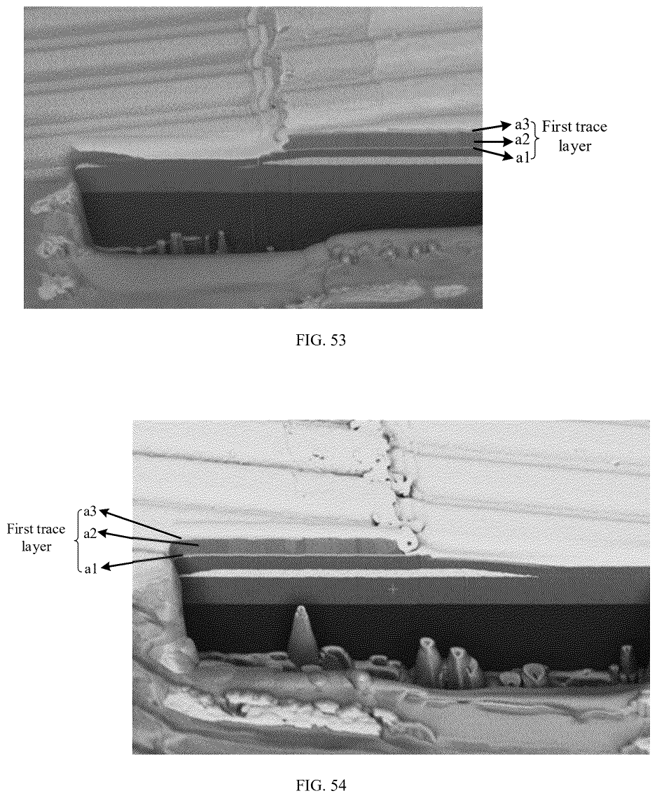

In order to avoid the region of the first trace layer that is not protected by the organic film layer in an I-shaped structure, the third material layer a3 of the first trace layer can be etched using an etching process. Referring to FIG. 52, after the etching is completed, there may still be an internal etching of the second material layer a2. As a result, referring to FIG. 53 and FIG. 54, in order to ensure the removing of the I-shaped structure, it is necessary to ensure that the distance between the third boundary of the third trace layer a3 and the first boundary of the first trace layer a1 is greater than 3 μm.

In summary, the embodiments of the present disclosure provide a method for preparing a display panel. In the method, a first trace layer of a power supply trace in the display panel has a first target region exposed by a through-slot region of a first organic film layer, and an orthographic projection of a third material layer of the first trace layer in the first target region is within an orthographic projection of the second material layer on the base substrate. An orthographic projection of the second material layer of the first trace layer in the first target region on the base substrate is within an orthographic projection of the first material layer on the base substrate. As a result, the subsequent formation of an encapsulation film layer of the display panel can be prevented from generating cracks in the first target region, and thus water and oxygen can be prevented from intruding into the display region along the intrusion channel generated by the cracks. The solution of the embodiments of the present application can ensure the light-emitting effect of the pixel units in the display region, avoid the occurrence of black-spot defects in the display region, have a higher yield of the display panel, and have a better display effect of the display panel.

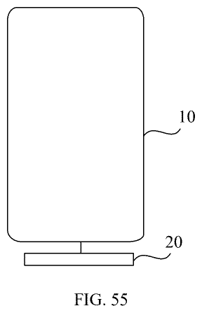

FIG. 55 is a schematic structural diagram of a display device according to some embodiments of the present disclosure. Referring to FIG. 55, the display device includes a power supply assembly 20 and a display panel 10 as provided in the above embodiments. The power supply assembly 20 is configured to supply power to the display panel 10.

In some embodiments, the display device may be a low-temperature polycrystalline oxide (LTPO) display device, a low-temperature poly-silicon (LTPS) display device, or an organic light-emitting display (OLED) display device. The display device may be any suitable display device including, but not limited to, cell phones, tablet computers, televisions, monitors, laptops, digital photo frames, navigators, e-books, and any other product or component with a display function.

As the display device has essentially the same technical effect as the display panel described in the previous embodiments, the technical effect of the display device will not be repeated here for the purpose of brevity.

The terms used in the embodiments of the present disclosure are used only for the purpose of explaining the embodiments of the present disclosure and are not intended to limit the present disclosure. Unless otherwise defined, technical terms or scientific terms used in the embodiments of the present disclosure should have the ordinary meaning understood by a person of ordinary skill in the field to which the present disclosure belongs.

The terms used in the embodiments of the present disclosure are merely intended for the purpose of explaining the embodiments of the present disclosure and are not intended to limit the present disclosure. Unless otherwise defined, technical or scientific terms used in the embodiments of the present disclosure shall have the same meanings as commonly understood by a person of ordinary skill in the art to which the present disclosure belongs. The terms “first,” “second,” “third,” and the like used in the specification and the claims of the present disclosure do not indicate any order, number, or importance, but are used only to distinguish between different components. Likewise, similar words “a” or “an” do not indicate a quantity limitation, but indicate that there is at least one. The terms “include” or “comprise” and the like are intended to indicate that the elements or objects before “include” or “comprise” encompass the elements or objects listed after “include” or “comprise” and their equivalents, and do not exclude other elements or objects. The terms “connect” or “connected” and the like are not limited to physical or mechanical connections, but may include electrical connections, whether direct or indirect. The terms “upper,” “lower,” “left,” “right,” etc. are only used to represent relative position relationships, and when the absolute position of the object to be described changes, the relative position relationship may also be changed accordingly.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

1. A display panel, comprising:
a base substrate, having a display region and a peripheral region surrounding the display region;
a plurality of pixel units, disposed in the display region;
a barrier structure, surrounding the display region;
at least one power supply trace, disposed on a side of the base substrate, wherein each of the at least one power supply trace is configured to receive a power supply signal and connected to the plurality of pixel units;
a first organic film layer, disposed on a side of the power supply trace away from the base substrate and provided with at least one through-slot region, wherein an orthographic projection of the through-slot region on the base substrate and an orthographic projection of the barrier structure on the base substrate are adjacent, and the through-slot region is configured to expose a first target region of the power supply trace;
wherein the power supply trace comprises at least a first trace layer comprising a first material layer, a second material layer, and a third material layer that are stacked sequentially in a direction away from the base substrate, wherein an orthographic projection of a third material layer of the first trace layer disposed in the first target region on the base substrate is within an orthographic projection of the second material layer on the base substrate, and an orthographic projection of a second material layer of the first trace layer disposed in the first target region on the base substrate is within an orthographic projection of the first material layer on the base substrate.

2. The display panel according to claim 1, wherein a first material layer of the first trace layer disposed in the first target region has a first boundary extending in a first direction, and the second material layer of the first trace layer disposed in the first target region has a second boundary extending in the first direction, and the third material layer of the first trace layer disposed in the first target region has a third boundary extending in the first direction;
wherein a distance, in a second direction, between the first boundary and the third boundary is greater than 3 micrometers, and the second boundary is disposed between the first boundary and the third boundary, the second direction being perpendicular to the first direction.

3. The display panel according to claim 1, wherein the first organic film layer is provided with a groove region, a thickness of the first organic film layer in the groove region being less than a thickness of the first organic film layer in other regions except the groove region, and the groove region being configured to cover a second target region of the first trace layer;
wherein the second target region and the first target region are adjacent in a first direction.

4. The display panel according to claim 3, wherein the groove region has a first groove boundary close to the first trace layer and extending in the first direction, and the third material layer of the first trace layer disposed in the first target region has a third boundary extending in the first direction;
wherein an orthographic projection of the first groove boundary on the base substrate is collinear with an orthographic projection of the third boundary on the base substrate;
wherein the groove region further has a second groove boundary away from the through-slot region and extending in a second direction and a third groove boundary adjacent to the through-slot region and extending in the second direction, the second direction being perpendicular to the first direction; wherein a distance, in the first direction, between the second groove boundary and the third groove boundary is greater than 3 micrometers.

5. (canceled)

6. The display panel according to claim 1, wherein the power supply trace comprises a third trace layer, a second trace layer, and the first trace layer that are stacked sequentially in the direction away from the base substrate; and the display panel comprises a third organic film layer disposed between the third trace layer and the second trace layer and a second organic film layer disposed between the second trace layer and the first trace layer, the first organic film layer being disposed on a side of the first trace layer away from the base substrate;
wherein the third trace layer and the second trace layer are connected through an first opening, the second trace layer and the first trace layer are connected through an second opening; wherein the first opening is in the third organic film layer, the second opening is in the second organic film layer, and the through-slot region is configured to expose the first target region of the first trace layer.

7. The display panel according to claim 1, wherein the power supply trace comprises a second trace layer and the first trace layer that are stacked sequentially in the direction away from the base substrate; and the display panel comprises a second organic film layer disposed between the second trace layer and the first trace layer, the first organic film layer being disposed on a side of the first trace layer away from the base substrate;
wherein the second trace layer and the first trace layer are connected through an opening in the second organic film layer, and the through-slot region is configured to expose the first target region of the first trace layer.

8. The display panel according to claim 1, wherein the at least one power supply trace comprises a first signal power supply trace and a second signal power supply trace that are spaced apart in a second direction, and the through-slot region has a first sub-through-slot region for exposing the first signal power supply trace and a second sub-through-slot region for exposing the second signal power supply trace;
wherein a length of the first sub-through-slot region in a first direction is less than or equal to a length of the second sub-through-slot region in the first direction.

9. The display panel according to claim 1, wherein a thickness of a portion of the second material layer disposed in the first target region is less than or equal to a thickness of a portion of the second material layer disposed in other regions;
wherein in a case that the thickness of the portion of the second material layer disposed in the first target region is less than the thickness of the portion of the second material layer disposed in the other regions, a surface, away from the base substrate, of the portion of the second material layer disposed in the first target region is uneven.

10. (canceled)

11. The display panel according to claim 1, wherein the barrier structure comprises a first barrier dam, a second barrier dam, and a third barrier dam that are arranged sequentially in a direction away from the display region;
wherein the first organic film layer is provided with two through-slot regions, wherein one of the through-slot regions is disposed on a side of the third barrier dam away from the display region, and another of the through-slot regions is disposed between the second barrier dam and the third barrier dam;
wherein each barrier dam in the barrier structure comprises at least one of organic film layers in the display panel, the organic film layers in the display panel comprising a third organic film layer, a second organic film layer, and the first organic film layer;
wherein one of the first organic film layer, the second organic film layer, and the third organic film layer is disposed in a region adjacent to any barrier dam in the barrier structure and not provided with the through-slot region.

12. (canceled)

13. The display panel according to claim 1, wherein in a region of the power supply trace that is covered by an organic film layer in the display panel, side edges of the third material layer, the second material layer, and the first material layer are flat side edges, and the flat side edges are inclined relative to a carrying surface of the base substrate;
wherein an orthographic projection of the third material layer on the base substrate is within the orthographic projection of the second material layer on the base substrate, and the orthographic projection of the second material layer on the base substrate is within the orthographic projection of the first material layer on the base substrate.

14. A method for preparing a display panel, comprising:
providing a base substrate, wherein the base substrate has a display region and a peripheral region surrounding the display region;
forming a plurality of pixel units, a barrier structure, and at least one initial power supply trace on a side of the base substrate, wherein the plurality of pixel units are disposed in the display region, the barrier structure surrounds the display region, and each of the at least one initial power supply trace is configured to receive a power supply signal and connected to the plurality of pixel units; and the initial power supply trace comprises at least a first initial trace layer comprising a first material layer, a second material layer, and a third material layer that are stacked sequentially in a direction away from the base substrate;
forming an initial organic film layer on a side of the initial power supply trace away from the base substrate, wherein the initial organic film layer is provided with at least one through-slot region, an orthographic projection of the through-slot region on the base substrate and an orthographic projection of the barrier structure on the base substrate being adjacent, and the through-slot region being configured to expose a first target region of the initial power supply trace; and
acquiring a first trace layer of at least one power supply trace and a first organic film layer by etching, using an etching process, a third material layer of the first initial trace layer of the at least one initial power supply trace disposed in the first target region and etching the initial organic film layer, wherein an orthographic projection of a third material layer of the first trace layer disposed in the first target region on the base substrate is within an orthographic projection of the second material layer on the base substrate, and an orthographic projection of a second material layer of the first trace layer disposed in the first target region on the base substrate is within an orthographic projection of the first material layer on the base substrate.

15. The method according to claim 14, wherein said forming the plurality of pixel units comprises: forming an anode layer, a pixel definition layer, a light-emitting layer, and a cathode layer sequentially on a side of the initial organic film layer away from the base substrate; and
said etching, using the etching process, the third material layer of the first initial trace layer of the at least one initial power supply trace disposed in the first target region and etching the initial organic film layer comprises:
etching, after forming the anode layer and before forming the pixel definition layer, the third material layer of the first initial trace layer of the at least one initial power supply trace disposed in the first target region and etching the initial organic film layer using the etching process.

16. The method according to claim 15, wherein before forming the anode layer, a first boundary of the first material layer of the first initial trace layer disposed in the first target region, a second boundary of the second material layer of the first initial trace layer disposed in the first target region, and a third boundary of the third material layer of the first initial trace layer disposed in the first target region are collinear; and
after forming the anode layer, an orthographic projection of a second material layer of the first initial trace layer disposed in the first target region on the base substrate is within an orthographic projection of the third material layer on the base substrate, and the first boundary of the first material layer of the first initial trace layer disposed in the first target region and the third boundary of the third material layer are collinear;
wherein the first boundary, the second boundary, and the third boundary all extend in a first direction.

17. The method according to claim 14, wherein said forming the plurality of pixel units comprises: forming an anode layer, a pixel definition layer, a light-emitting layer, and a cathode layer sequentially on a side of the first organic film layer away from the base substrate; and
said etching, using the etching process, the third material layer of the first initial trace layer of the at least one initial power supply trace disposed in the first target region and etching the initial organic film layer comprises:
etching, after forming the pixel definition layer and before forming the light-emitting layer, the third material layer of the first initial trace layer of the at least one initial power supply trace disposed in the first target region and etching the initial organic film layer using the etching process.

18. The method according to claim 17, wherein before forming the pixel definition layer, the orthographic projection of the second material layer of the first initial trace layer disposed in the first target region on the base substrate is within the orthographic projection of the third material layer on the base substrate, and the first boundary of the first material layer of the first initial trace layer disposed in the first target region and the third boundary of the third material layer are collinear;
after forming the pixel definition layer, a portion of a material of the pixel definition layer is disposed in an indented region, the indented region being a region where the first initial trace layer is provided with a first material layer and a third material layer and not provided with a second material layer; and
after etching, using the etching process, the third material layer of the first initial trace layer of the at least one initial power supply trace disposed in the first target region and etching the initial organic film layer, the portion of the material of the pixel definition layer in the indented region is removed.

19. The method according to claim 14, wherein said etching, using the etching process, the third material layer of the first initial trace layer of the at least one initial power supply trace disposed in the first target region and etching the initial organic film layer comprises:
coating a photoresist on a side of the first initial trace layer away from the base substrate;
exposing the photoresist using a mask;
developing the photoresist using a developer to remove a portion of the photoresist as exposed;
removing, using the etching process, a portion of the third material layer of the first initial trace layer disposed in the first target region and a portion of the initial organic film layer that are not protected by the photoresist; and
removing a remaining photoresist.

20. The method according to claim 19, wherein the mask has a plurality of mask openings, wherein an orthographic projection of each of the mask openings on the base substrate partially overlaps the through-slot region and partially overlaps the first target region of the initial power supply trace; and
the mask opening has a first mask boundary extending in a first direction, wherein the first mask boundary is configured to form a third boundary of the third material layer that is etched, and an orthographic projection of the first mask boundary on the base substrate is within the orthographic projection of the first material layer on the base substrate, and a distance, in a second direction, between the first mask boundary and a first boundary is greater than 3 micrometers, the second direction being perpendicular to the first direction;
wherein the first mask boundary is further configured to form a first groove boundary of a groove region of the first organic film layer that is etched, the first groove boundary being close to the first trace layer and extending in the first direction; and a thickness of the first organic film layer in the groove region is less than a thickness of the first organic film layer in other regions except the groove region, and the groove region is configured to cover a second target region of the power supply trace, the second target region and the first target region being adjacent in the first direction.

21. (canceled)

22. The method according to claim 20, wherein the mask opening further has a second mask boundary extending in the second direction, wherein the through-slot region is disposed on a side of the second mask boundary, and the second mask boundary is configured to form a second groove boundary of the groove region of the first organic film layer that is away from the through-slot region and extends in the second direction; and the groove region further has a third groove boundary adjacent to the through-slot region and extending in the second direction;
wherein a distance, in the first direction, between the second groove boundary and the third groove boundary is greater than 3 micrometers.

23. The method according to claim 14, wherein said forming the power supply trace comprises: forming a first trace layer on the side of the base substrate; or
said forming the power supply trace comprises: forming a second trace layer, a second organic film layer, and the first trace layer sequentially on the side of the base substrate, the first trace layer and the second trace layer being connected through an opening in the second organic film layer; or
said forming the power supply trace comprises: forming a third trace layer, a third organic film layer, a second trace layer, a second organic film layer, and the first trace layer sequentially on the side of the base substrate, the first trace layer and the second trace layer being connected through an opening in the second organic film layer, and the second trace layer and the third trace layer being connected through an opening in the third organic film layer;
wherein the through-slot region is configured to expose a first target region of the first trace layer.

24. A display device, comprising: a power supply assembly and a display panel;
wherein the power supply assembly is configured to supply power to the display panel; and
the display panel comprises:
a base substrate, having a display region and a peripheral region surrounding the display region;
a plurality of pixel units, disposed in the display region;
a barrier structure, surrounding the display region;
at least one power supply trace, disposed on a side of the base substrate, wherein each of the at least one power supply trace is configured to receive a power supply signal and connected to the plurality of pixel units;
a first organic film layer, disposed on a side of the power supply trace away from the base substrate and provided with at least one through-slot region, wherein an orthographic projection of the through-slot region on the base substrate and an orthographic projection of the barrier structure on the base substrate are adjacent, and the through-slot region is configured to expose a first target region of the power supply trace;
wherein the power supply trace comprises at least a first trace layer comprising a first material layer, a second material layer, and a third material layer that are stacked sequentially in a direction away from the base substrate, wherein an orthographic projection of a third material layer of the first trace layer disposed in the first target region on the base substrate is within an orthographic projection of the second material layer on the base substrate, and an orthographic projection of a second material layer of the first trace layer disposed in the first target region on the base substrate is within an orthographic projection of the first material layer on the base substrate.
